(19) United States
(12) Patent Application Publication
(10) Pub. No.: US 2024/0251574 A1
(43) Pub. Date: Jul. 25, 2024

(54) PEROVSKITE-BASED MULTI-JUNCTION SOLAR CELL AND METHOD FOR PRODUCING SAME

(71) Applicant: Karlsruher Institut für Technologie, Karlsruhe (DE)

(72) Inventors: Raphael Schmager, Karlsruhe (DE); Ulrich W. Paetzold, Karlsruhe (DE); Julie Roger, Karlsruhe (DE); Paul Fassl, Heidelberg (DE); Tobias Abzieher, Ettlingen (DE)

(73) Assignee: Karlsruher Institut für Technologie, Karlsruhe (DE)

(21) Appl. No.: 18/547,778

(22) PCT Filed: Feb. 24, 2022
(86) PCT No.: PCT/EP2022/054677

§ 371 Date: Aug. 24, 2023

(30) Foreign Application Priority Data
Feb. 24, 2021 (DE) 102021201746.0

(51) Int. Cl. H10K 30/57; H10K 30/40; H10K 30/80

(52) U.S. Cl. CPC H10K 30/57; H10K 30/40; H10K 30/80

(57) ABSTRACT

The invention relates to a perovskite-based multi-junction solar cell (110) and to a method for producing same. The method comprises the following steps: a) producing a first layer stack (112), wherein the first layer stack (112) has at least one substrate (116), at least one first electrode (118) and at least one first layer (120); b) producing a second layer stack (114), wherein the second layer stack (114) has at least one absorber layer (130) and at least one second layer (134); wherein in step a) a perovskite layer (124) is introduced into the first layer stack (112) or in step b) the perovskite layer (124) is introduced into the second layer stack (114), wherein the method also has the following steps: c) applying the first layer stack (112) to the second layer stack (114); d) laminating the first layer stack (112) with the second layer stack (114) such that at least one connection selected from the group consisting of a mechanical and an electrical connection is formed between the first layer stack (112) and the second layer stack (114), wherein the perovskite-silicon multi-junction solar cell (110) is formed; wherein the first layer (120) and the second layer (134) are each selected from the group consisting of a hole transport layer (122), an electron transport layer (136), a buffer layer (137), a recombination layer (132) or an electrode layer; wherein the perovskite layer (124) forms a laminate-forming layer of either the first layer stack (112) or the second layer stack (114).

### FIELD OF THE INVENTION

The present invention relates to a perovskite-based multi-junction solar cell and to a method of production thereof. The invention is located more particularly in the field of optoelectronics. However, other applications are also conceivable in principle.

### PRIOR ART

Extensive research in the field of photovoltaics (PV) based on perovskite semiconductors in the last decade has led to rapid development. In particular, efficiencies of more than 25% have already been achieved for single-junction perovskite solar cells. Hybrid organic-inorganic metal halide-perovskite semiconductors are also drawing an enormous amount of attention because of their exceptional optoelectronic properties, such as their high coefficients of absorption, their high charge carrier mobilities and their low recombination rates.

An adjustable bandgap of these perovskites through variation of a composition of the halide anion in a perovskite crystal structure fundamentally enables strong light absorption within a broad spectral range. With low material costs and a wide range of possible deposition techniques, perovskites are qualified in principle as promising candidates for a next generation of multi-junction solar cells. Multi-junction solar cells combine multiple absorbers, which means that efficiency is in principle well above the efficiency of single-junction solar cells. Therefore, perovskites are of interest for these multi-junction solar cells in particular, since efficiency can be increased by a combination of established photovoltaic technologies, such as wafer-based silicon or copper-indium-gallium diselenide solar cells. This means that the perovskite-based solar cells are currently a promising technology for the future photovoltaics market.

Perovskite solar cells thus show fundamentally high efficiencies and are ideally suited in principle to multi-junction solar cells by virtue of their good optoelectronic properties.

The prior art describes single-junction solar cells and multi-junction solar cells based on perovskite.

U.S. Pat. No. 10,229,791 B2 describes a method of producing a perovskite solar cell by a non-deposition method. More particularly, the method comprises producing a first substrate by forming a hole transport layer atop a light-absorbing layer in a semidried state and pressurizing and drying a second substrate with an electrode opposite the first substrate.

The publication S. P. Dunfield et al., Curtailing perovskite processing limitations via lamination at the perovskite/perovskite interface, ACS Energy Lett. (2018), doi:10.1021/acsenergylett.8b00548, describes a method in which two transparent conductive oxide/transport material/perovskite half-stacks are produced independently of one another and then laminated together at the perovskite/perovskite interface.

WO 2017/200732 A1 describes production of a laminated structure by providing a first substrate having a n-type oxide layer on a first surface and a second substrate having a p-type oxide layer on a first surface. The first surface of the first substrate or the first surface of the second substrate has, or both have, a liquid halide layer. The first substrate is pressed in contact with the second substrate, such that the first surface of the first substrate is in contact with the first surface of the second substrate. The halide layer is then solidified in order to form the laminated structure.

WO 2019/173803 A1 describes a method comprising positioning of a stack having at least one of the following layers between a first surface and a second surface: a first perovskite layer and/or a second perovskite layer; and treating the stack for a period by heating the stack and/or by pressurizing the stack, wherein an apparatus having the first surface and the second surface provides the heating and the pressurizing of the stack.

The publication H. Kanda et al., Interface Optoelectronics Engineering for Mechanically Stacked Tandem Solar Cells Based on Perovskite and Silicon, ACS Appl. Mater. Interfaces. (2016), doi:10.1021/acsami.6b07781, describes a development of photonic components having antireflective properties and of electronic components for extraction of the hole using 2.5 nm of a thin Au layer for two- and four-terminal tandem solar cells using CH₃NH₃PbI₃ perovskite (upper cell) and p-type single-crystal silicon.

It is generally the case that individual layers of solar cells or perovskite-based multi-junction solar cells, for example of a perovskite-silicon multi-junction solar cell, can be produced by various processes. These comprise, for example, vacuum coating methods, liquid phase processes and a combination of the two. The applying of the perovskite layer in a perovskite solar cell and of further layers to the silicon solar cell can be achieved by a sequential sequence of the layers.

US2020/0212243 A1 describes a method of producing a monolithic tandem solar cell in which a perovskite solar cell is laminated onto and bound to a silicon solar cell. According to the present disclosure, a first microporous precursor thin film is formed by a sputtering method on a substrate with an unevenly structured texture, and then a thin halide film is formed atop the first microporous precursor thin film in order to form a perovskite absorption layer, wherein reflection of light can be reduced and wherein an optical path length can be increased. Accordingly, a light absorption rate can be increased.

Laminating the perovskite layer of the perovskite solar cell onto the silicon solar cell in principle eliminates a limitation that results from complete sequential production. The applying of layers by means of a lamination process is fundamentally already known for encapsulation, contact and charge carrier transport layers.

There are fundamentally multiple patents and publications relating to the lamination of perovskite solar cells or of the perovskite absorber. The patents and publications fundamentally address the laminating of a perovskite layer onto another layer for perovskite solar cells, and the laminating of perovskite layers with liquid perovskite or charge transport layers.

EP 3 244 455 A1 describes a method of producing a device comprising an inorganic/organic hybrid perovskite compound film. The method comprises the following steps: a) laminating a first structure and a second structure in order to enable contact between the first surface layer and the second surface layer, wherein the first structure comprises a first surface layer including at least one of materials i) to v), wherein the second structure comprises a second surface layer including, independently of the first surface layer, at least one of materials i) to v); and b) applying heat and physical force to the laminate, wherein the first structure and the second structure are laminated: i) an inorganic/organic hybrid perovskite compound, ii) an organic halide, iii) a metal halide, iv) an inorganic/organic hybrid perovskite compound precursor and v) a metal halide precursor.

In addition, the patents and publications discuss in principle joining a perovskite layer to another layer for perovskite solar cells with the aid of a transparent conductive adhesive.

The publication C. O. Ramírez Quiroz et al., Interface Molecular Engineering for Laminated Monolithic Perovskite/Silicon Tandem Solar Cells with 80.4% Fill Factor, Adv. Funct. Mater. (2019), doi:10.1002/adfm.201901476, describes a multipurpose bonding layer based on poly(3,4-ethylenedioxythiophene) doped with poly(styrenesulfonate) (PEDOT:PSS) and d-sorbitol for monolithic perovskite/silicon tandem solar cells.

The publication I. Y. Choi et al., Two-terminal mechanical perovskite/silicon tandem solar cells with transparent conductive adhesives, Nano Energy. (2019), doi:10.1016/j.nanoen.2019.104044, describes a novel mechanical tandem solar cell composed of perovskite and silicon with two terminals, which is produced by bonding a silicon cell in the reverse direction to a perovskite cell using a transparent conductive adhesive (TCA).

US 2016/0111223 A1 describes an optoelectronic device. The device comprises: (a) an upper device component comprising: a counterelectrode composed of a metal, a conductive oxide or a conductive organic compound; (b) a lower device component comprising: a glass or polymeric carrier substrate, a working electrode comprising a transparent conductive coating as well as the glass or polymer substrate, a blocking layer, an active layer, a hole-conducting layer, (c) a conductive adhesive disposed between the upper device component and the lower upper device component, and (d) a contact layer for facilitation of the injection of electrons into the active layer between and in contact with the conductive adhesive and the hole-conducting layer.

Additionally described is lamination of two independently produced half-stacks of a perovskite solar cell in the publication R. Schmager et al., Laminated Perovskite Photovoltaics: Enabling Novel Layer Combinations and Device Architectures, Adv. Funct. Mater. (2020), doi:10.1002/adfm.201907481.

The relatively new technology of the perovskite-based solar cells fundamentally still needs to master a few challenges, for example assurance of improved long-term stability and stability at high temperatures. Moreover, material selection in sequential layer deposition is fundamentally limited by process or material incompatibilities. This is fundamentally because it is necessary to ensure that any further layer which is applied does not destroy the one before. The destruction may in principle result from incompatible solvents, excessively high process temperatures or mechanical destruction by high-energy particles, for example in physical gas phase deposition.

Lamination with a conductive transparent adhesive in principle requires a further layer that can cause additional and/or unwanted optical and/or electrical losses. Lamination via a “semi-”dry hole transport layer fundamentally restricts the process via the selection of possible hole transport materials. Since one dry and one semi-dry layer is required on each one of the layer stacks, it is fundamentally possible to use only a solvent-based approach that fundamentally entails solvent incompatibilities. The lamination of a wet perovskite layer is fundamentally difficult to scale up. The lamination of two perovskite layers fundamentally requires the application of the perovskite to both layer stacks. This is firstly fundamentally more difficult/complex, and secondly fundamentally further limits the selection of material beneath the perovskite layer.

### OBJECT OF THE INVENTION

Proceeding therefrom, it is the object of the present invention to provide a perovskite-based multi-junction solar cell and a method of production thereof that at least partly overcome the detailed disadvantages and limitations of the prior art. More particularly, the perovskite-based multi-junction solar cell and the method of production thereof are to increase long-term stability of perovskite-based multi-junction solar cells and enable new combinations of materials and layers.

### DISCLOSURE OF THE INVENTION

This object is achieved by a perovskite-based multi-junction solar cell and by a method of production thereof, having the features of the independent claims. For further details, reference is made to the features of the dependent claims, the rest of the description and to the figures.

The terms “have”, “comprise”, “contain” or “include”, or any grammatical variations thereof, are used in a non-exclusive manner hereinafter. Accordingly, these terms may relate either to situations in which there are no further features aside from the features introduced by these terms or to situations in which there are one or more further features. For example, the expression “A has B”, “A comprises B”, “A contains B” or “A includes B” may relate to the situation in which, apart from B, there is no further element in A (i.e. to a situation in which A consists exclusively of B), or to the situation in which, in addition to B, there are one or more further elements in A, for example element C, elements C and D or even further elements.

In addition, it is pointed out that the expressions “at least one” and “one or more”, and grammatical variations of these expressions, when they are used in association with one or more elements or features and are intended to express that the element or feature may be present once or more than once, are generally used just once, for example in the first introduction of the feature or element. In any subsequent new mention of the feature or element, the corresponding expression “at least one” or “one or more” is generally not used again without limitation of the possibility that the feature or element may be present once or more than once.

In addition, the expressions “preferably”, “especially”, “for example” or similar expressions are used in conjunction with optional features below without alternative embodiments being limited thereby. Thus, features that are introduced by these terms are optional features, and there is no intention that these features restrict the scope of protection of the claims and in particular of the independent claims. Thus, the invention, as the person skilled in the art will recognize, can also be performed using other configurations. In a similar manner, features that are introduced by “in one embodiment of the invention” or by “in one working example of the invention” are considered to be optional features without any intention to thereby restrict alternative configurations or the scope of protection of the independent claims. In addition, these introductory expressions are intended to have no effect on any possible combinations of features introduced thereby with other features, whether they are optional or non-optional features.

The words “first” and “second” should be regarded as mere descriptions without specifying any sequence or priority, and, for example, without ruling out the option that multiple types of first elements or second elements or exactly one type of each may be provided. Moreover, additional elements, for example one or more third elements, may be present.

In a first aspect of the present invention, a method of producing a perovskite-based multi-junction solar cell is described.

The method may comprise the method steps described hereinafter. The method steps may especially be conducted in the sequence specified. However, a different sequence is likewise conceivable. In addition, one or more method steps may be conducted simultaneously or overlapping in time. In addition, one, more than one or all the method steps may be performed once or else repeatedly. The method may additionally still comprise further method steps.

The method comprises the following steps:
a) producing a first layer stack, where the first layer stack comprises at least one substrate, at least one first electrode and at least one first layer;
b) producing a second layer stack, where the second layer stack comprises at least one absorber layer and at least one second layer.

In step a), a perovskite layer is introduced into the first layer stack or, in step b), the perovskite layer is introduced into the second layer stack. Optionally, in step a), a perovskite layer can be introduced into the first layer stack and, in step b), a perovskite layer can be introduced into the second layer stack. The method further comprises the following steps:
c) applying the first layer stack to the second layer stack;
d) laminating the first layer stack with the second layer stack, in such a way that at least one connection selected from the group consisting of: a mechanical connection, an electrical connection, is formed between the first layer stack and the second layer stack, forming the perovskite-based multi-junction solar cell.

The first layer and the second layer are each selected from the group consisting of: a hole transport layer, an electron transport layer, a buffer layer, a recombination layer, an electrode layer. The perovskite layer forms a laminate-forming layer either of the first layer stack or of the second layer stack.

The second layer stack may also comprise at least one second electrode.

The first or second layer stack may comprise a recombination layer.

The expression “multi-junction solar cell” refers to a solar cell having two or more absorber layers that convert incident light to electrical current. The absorber layers may especially be layered one on top of another. The uppermost absorber layer facing the light absorbs light having a short wavelength and allows longer-wave light to pass through. The second absorber layer beneath in turn absorb a portion of the spectrum up to a limiting wavelength which, in the case of semiconductors, is determined by what is called a bandgap energy. The multi-junction solar cell may therefore also be described as a “stack solar cell”. In particular, it may be a multi-junction solar cell having exactly two absorber layers. The multi-junction solar cell having exactly two absorber layers may also be referred to as tandem solar cell. The expression “perovskite-based multi-junction solar cell” therefore refers fundamentally to a multi-junction solar cell, wherein at least one of the absorber layers comprises perovskite. The further absorber layer may especially comprise silicon. In addition, the further absorber layer may be or comprise a solar cell, especially a silicon solar cell. In addition, the further absorber layer may comprise perovskite. In addition, the further absorber layer may be an organic or inorganic absorber layer comprising, for example, copper-indium-gallium diselenide (CIGS). Other configurations are also possible in principle. Further possible materials for the further absorber layer are described hereinafter.

The term “layer” fundamentally defines any element of cuboidal shape, the extent of which in one dimension is referred to as thickness. The layer may especially have a thickness in the nanometer range to the micrometer range. In particular, the layer may have a thickness up to 5 μm. The layer may be a continuous layer. Alternatively, the layer may, however, be interrupted in one or more places, for example by depressions or interruptions. The layer may be deposited or applied to a substrate or to a further layer. Illustrative production methods are described in detail hereinafter.

A “layer stack” is to be understood in principle in the context of the present invention to mean a sequence of at least two layers applied directly to one another or with insertion of one or more interlayers. The layer stack may comprise multiple layers of the same material. In addition, the layer stack may comprise layers of different materials. Other embodiments are also conceivable in principle. The layer stack may especially have at least three layers. A different number of layers is also conceivable in principle. The layers may be delimited from one another by interfaces. The interfaces may be planar or textured. The “layer stack” may therefore also be referred to as “layer construction”. The layer stack may additionally also comprise elements other than layers. In particular, as elucidated in detail hereinafter, the first electrode and/or the second electrode may optionally take the form of a finger electrode, grid or grid-like electrode. The first electrode and/or the second electrode may especially be disposed between layers of the first layer stack or of the second layer stack.

The layers of the first layer stack may be in a mutually superposed arrangement. In addition, the layers of the second layer stack may be in a mutually superposed arrangement. The expression “mutually superposed” refers in principle to a position of a surface relative to another surface, where the two surfaces are arranged opposite one another. In particular, the first surface and the second surface may be in direct contact with one another. In particular, the second layer may lie atop the first layer, where the first surface and the second surface are at least partly in contact. In such an arrangement, the second layer may, for example, have smaller dimensions, especially a shorter length and/or width, than the first layer or vice versa. It is possible here for parts of the second surface to be uncovered by the first layer, or vice versa. In addition, the first layer and the second layer may be in a mutually offset arrangement, meaning that a portion of the second layer may project beyond an edge of the first layer or vice versa.

The “producing of a layer stack” in principle refers to any operation that may comprise deposition or application of one or more layers of the layer stack to a substrate or to another layer. In particular, it is possible to use at least one deposition method selected from the group consisting of: sputtering, electron beam evaporation, thermal evaporation, rotary coating, blade coating, inkjet printing, spray coating, slot die coating, roll coating, gravure printing methods, atomic layer deposition. However, other methods are also conceivable in principle. In particular, it is possible to apply a layer of SnOₓ by atomic layer deposition.

The term “absorber layer” refers in principle to any layer including at least one charge carrier-generating layer.

The perovskite layer may be set up as an absorber layer. The term “perovskite layer” in principle refers to any layer including or comprising perovskite. The term “perovskite” refers in principle to any material. One example is 3D perovskites having a chemical ABX₃ structure where X may be iodine, bromine or chlorine (or any mixture of these), where B may be lead or tin (or any mixture of these), where A may be methylammonium, formamidinium, cesium, potassium or rubidium (or any mixture of these). Any variances and impurities in the chemical structure of the 3D perovskites mentioned are also included in principle. A further example is that of low-dimensional perovskites, the chemical structure of which differs from the ABX₃ structure, and which form 2D materials. The perovskite layer is especially producible by means of at least one deposition method selected from the group consisting of: thermal evaporation, rotary coating, blade coating, inkjet printing, spray coating, slot die coating, roll coating, gravure printing methods. However, other methods are also conceivable in principle. In particular, the perovskite layer may be applied to the first layer stack or to the second layer stack by means of at least one method selected from the group consisting of: thermal evaporation, rotary coating, blade coating, inkjet printing, spray coating, slot die coating, roll coating, gravure printing methods.

As stated above, in step a), the perovskite layer is introduced into the first layer stack or, in step b), the perovskite layer is introduced into the second layer stack. The first layer stack or the second layer stack may comprise the perovskite layer. The first layer stack may have several layers, and one of the layers may be the perovskite layer. The second layer stack may have several layers, and one of the layers may be the perovskite layer. Optionally, the first layer stack and/or the second layer stack may each have at least one further perovskite layer.

The absorber layer of the second layer stack may especially include or comprise silicon. The absorber layer of the second layer stack may therefore also be referred to as “silicon layer”. The silicon may especially take the form of monocrystalline, polycrystalline or amorphous silicon having a p-n junction or a p-i-n junction. The silicon may either be planar or textured, as set out in detail hereinafter. In addition, the absorber layer of the second layer stack may be or comprise a solar cell, especially a silicon solar cell. However, other configurations are also conceivable in principle.

The term “substrate” in principle refers to any element with the property of bearing one or more further elements, and which accordingly has mechanical stability. The substrate of the first layer stack may especially be of transparent configuration. The substrate of the first layer stack may also take the form of a flexible substrate. The substrate of the first layer stack may have been produced from a polymer, especially from polyethylene terephthalate (PET) and/or polyethylene naphthalate (PEN) and/or ethylene-vinyl acetate (EVA). The substrate of the first layer stack may also have been produced from a glass. The glass may have a thickness of 5 μm to 5 mm, especially of 25 μm. In addition, the substrate of the first layer stack may take the form of a rigid substrate, especially of a rigid substrate made of glass.

The substrate may be set up for encapsulation of the perovskite-based multi-junction solar cell, especially after performance of step d). By sequential production after application of all optically and electrically functional layers, the encapsulation may be set up in order to protect the perovskite-based multi-junction solar cell from outside influences, such as water, oxygen and/or reactive substances. By virtue of the lamination, the substrate, especially glass or a film, may already form a bounding layer directly after the lamination. In this way, in principle, a greatly simplified process step sequence is possible. In addition, it is possible in principle to increase stability of the perovskite-based multi-junction solar cell.

The substrate may especially be a colored substrate. The colored substrate may especially include or comprise a film and/or glass. It is thus possible to adjust a color or a visual perception of the perovskite-based multi-junction solar cell. Perovskite-based multi-junction solar cells with colored substrates may especially be used in building-integrated photovoltaics.

The substrate may optionally be removed from the perovskite-silicon multi-junction solar cell after performance of step d). For example, an anti-adhesive layer may be applied to the substrate, which may especially be set up for removal of the substrate from the perovskite-silicon multi-junction solar cell.

The substrate and/or at least one layer of the first layer stack and/or of the second layer stack may have at least one rough surface. The rough surface may arise from the production process. The rough surface may especially have a root mean square roughness of 1 nm to 2 μm, especially of 50 nm to 300 nm. The rough surface may also have a distance between a highest and a lowest point (peak-to-valley) of 1 nm to 10 μm, especially of 10 nm to 1 μm. The method of the invention can get round this roughness, which may be inherent to particular production methods, and may therefore constitute a benefit for industrial applications. This may be of particular relevance, for example, for CIGS bottom solar cells, which fundamentally have a rough surface as a result of the production method.

In addition, the substrate and/or at least one layer of the first layer stack and/or of the second layer stack may have at least one textured surface having at least one texture. The texture may have been created specifically by a production process. The textured surface may have a root mean square roughness of greater than 2 nm, especially of greater than 250 nm. In addition, the textured surface may have a distance between a highest and a lowest point (peak-to-valley) of 20 nm to 100 μm, especially of 500 nm to 10 μm. In particular, an outer face of the perovskite-based multi-junction solar cell which is exposed to sunlight and/or a reverse side of the perovskite-based multi-junction solar cell and/or a surface of a layer within the perovskite-based multi-junction solar cell, especially at an interface of the lamination in the perovskite-based multi-junction solar cell, may have the textured surface. In particular, a surface of the laminate-forming layer of the first layer stack and/or a surface of the laminate-forming layer of the second layer stack may be the textured surface. Of particular interest are in particular single- or double-sided textured silicon solar cells, the texture of which enables better light coupling that can improve absorption. It is thus possible to achieve higher efficiencies.

The texture may have been created either periodically or randomly. The texture may especially have a multitude of elements. For example, the texture may be a nanotexturing or a microtexturing. The term “nanotexturing” is in principle to be understood to mean any texture where the elevations and/or depressions of the surface have dimensions in the range from 1 or more nanometers, especially in the range from 10 nm to 1000 nm, preferably in the range from 50 nm to 800 nm, more preferably in the range from 100 nm to 500 nm. The term “microtexturing” is in principle to be understood to mean any texture where the elevations and/or depressions of the surface have dimensions in the range from 1 or more micrometers, especially in the range from 2 μm to 500 μm, preferably in the range from 5 μm to 100 μm, more preferably in the range from 10 μm to 50 μm. The dimensions may especially be a height, a width and/or a depth of the elevations or of the depressions. The elements may be configured as an elevation on a surface of a layer of the first layer stack and/or of the second layer stack. In particular, the elements may be isolated elements at a distance from adjacent elements. The elements may be configured with no contact with one another. Alternatively, the elements may be at least partly in contact. The elements may especially have at least one shape selected from the group consisting of: a conical shape, especially a frustoconical shape; a tetrahedral shape, especially a pyramidal shape; a cylindrical shape, especially a circular cylindrical shape or elliptical cylindrical shape; a spherical shape. Consequently, the texture may have at least one structure selected from the group consisting of: a conical shape, especially a frustoconical shape; a tetrahedral shape, especially a pyramidal shape; a cylindrical shape, especially a circular cylindrical shape or elliptical cylindrical shape; a spherical shape. Other embodiments are also conceivable in principle. The textured surface may have a self-cleaning action. In addition, the textured surface may improve optical properties of the perovskite-based multi-junction solar cell, especially in order that light can be absorbed effectively and high efficiencies of the perovskite-based multi-junction solar cell can be achieved.

For example, during step d), the at least one texture may be formed on the substrate. The substrate may be or comprise a film, and at least one surface of the film may receive a texture during the laminating by hot embossing. It is thus possible to achieve an additional functionality of the perovskite-based multi-junction solar cell without performing an additional process step. However, the textured surface may also have been formed on the substrate prior to performance of step d). It is especially possible to provide a textured film and/or a textured glass.

In addition, the substrate and/or at least one layer of the first layer stack and/or of the second layer stack may have at least one surface having defects. The defects may especially arise from imperfections in the production processes or the treatment steps or from degradation. The defects especially include impurities, residual process materials, scratches and/or foreign bodies, especially dust and/or particles. The method of the invention, especially by contrast with conventional production processes, is fundamentally tolerant to defects and therefore constitutes a benefit for industrial production. In particular, a production fault rate can be reduced.

In particular, one or more further layers of the first layer stack and/or of the second layer stack may have the textured surface and/or the rough surface. The further layers may especially be layers having a layer thickness of greater than 5 μm, especially of greater than 10 μm. In particular, the further layer may be the absorber layer, especially the solar cell. The solar cell may be selected from the group consisting of: a silicon solar cell, a perovskite solar cell. Other solar cells are also conceivable. In addition, the further layer may be the perovskite layer.

The textured surface of a layer or the substrate may in principle continue within the first layer stack or within the second layer stack through applying of additional layers, especially of additional layers having a layer thickness of less than 5 μm.

The term “electrode” in principle refers to any electron conductor and/or hole conductor that acts together with at least one further electrode, where there is a medium between in each case two of these electrodes, with which these electrodes interact. The electrode may especially comprise at least one electrically conductive material.

The first electrode of the first layer stack may especially be transparent. The first electrode may especially comprise at least one transparent conductive oxide selected from the group consisting of: indium tin oxide (ITO), indium zinc oxide (IZO), fluorine-doped tin oxide (FTO), hydrogen-doped indium oxide (IO:H), aluminum-doped zinc oxide (AZO). Other materials are also conceivable in principle. In addition, the first electrode may comprise at least one metal selected from the group consisting of: gold, silver, aluminum, copper, molybdenum (Mo). Other materials are also conceivable in principle. The first electrode may especially take the form of a layer. The first electrode may especially be produced by means of at least one deposition method selected from the group consisting of: sputtering, electron beam evaporation, thermal evaporation. However, other methods are also conceivable in principle.

The second electrode of the second layer stack may especially comprise at least one transparent conductive oxide selected from the group consisting of: indium tin oxide (ITO), indium zinc oxide (IZO), fluorine-doped tin oxide (FTO), hydrogen-doped indium oxide (IO:H), aluminum-doped zinc oxide (AZO). In addition, the second electrode may comprise at least one metal selected from the group consisting of: gold, silver, aluminum, copper. Other materials are also conceivable in principle. The second electrode may especially have a combination of two or more materials. The combination may comprise two or more materials one on top of another and/or two or more materials alongside one another. In particular, the combination may comprise narrow lines of gold on a continuous ITO layer. The second electrode may especially take the form of a layer. The second electrode may especially be produced by at least one deposition method selected from the group consisting of: sputtering, electron beam evaporation, thermal evaporation. However, other methods are also conceivable in principle.

The first electrode and/or the second electrode may comprise at least one conductive oxide and may have a layer thickness of 15 nm to 300 nm, preferably of 50 nm to 200 nm, more preferably of 100 nm to 150 nm. The first electrode and/or the second electrode may also comprise at least one metal and may have a layer thickness of 10 nm to 200 nm, preferably of 50 nm to 100 nm.

The first electrode and/or the second electrode may each take the form of a layer, in particular the form of a layer of the first layer stack or of the second layer stack. The first electrode and/or the second electrode may therefore take the form of a layer electrode. However, the first electrode and/or the second electrode need not necessarily take the form of a layer. Alternatively, the first electrode and/or the second electrode may take the form of a finger electrode, preferably of a finger electrode made of silver (Ag), of a grid or of a gridlike electrode. Other embodiments are also conceivable in principle.

The term “recombination layer” in principle refers to any layer of a solar cell in which recombination takes place, i.e. a spontaneous recombination of electrons with hole. The recombination layer may especially comprise at least one transparent conductive oxide selected from the group consisting of: indium tin oxide (ITO), indium zinc oxide (IZO), fluorine-doped tin oxide (FTO), hydrogen-doped indium oxide (IO:H), aluminum-doped zinc oxide (AZO). In addition, the recombination layer may comprise at least one metal selected from the group consisting of: gold, silver, aluminum, copper. Other materials are also conceivable in principle. The recombination layer may especially comprise a combination of two or more materials. The combination may comprise two or more materials one on top of another and/or two or more materials alongside one another. The recombination layer may especially be produced by at least one deposition method selected from the group consisting of: sputtering, electron beam evaporation, thermal evaporation. However, other methods are also conceivable in principle. The recombination layer may comprise at least one conductive oxide and may have a layer thickness of 1 nm to 100 nm, preferably of 5 nm to 50 nm, more preferably of 10 nm to 20 nm. The recombination layer may also comprise at least one metal and may have a layer thickness of 1 nm to 10 nm, preferably of 2 nm to 5 nm.

The terms “hole transport layer” and “electron transport layer” refer in principle to any charge transport layers that enable movement of the corresponding charge carriers. The hole transport layer may comprise at least one organic material selected from the group consisting of: a polymer, PTAA (poly[bis(4-phenyl)(2,4,6-trimethylphenyl)amine]), PEDOT:PSS (poly(ethylenedioxythiophene):poly(styrenesulfonate)), Poly-TPD (poly[N,N′-bis(4-butylphenyl)-N,N′-bis(phenyl)benzidine]), P3HT (poly(3-hexylthiophene)). In addition, the hole transport layer may comprise at least one material based on small molecules, especially spiro-OMeTAD (2,2′,7,7′-tetrakis(N,N-di-4-methoxyphenylamino)-9,9′-spirobifluorene). In addition, the hole transport layer may comprise at least one self-assembly monolayer selected from the group: 2PACz ([2-(9H-carbazol-9-yl)ethyl]phosphonic acid), (7) MeO-2PACz ([2-(3,6-dimethoxy-9H-carbazol-9-yl)ethyl]phosphonic acid. In addition, the hole transport layer may comprise at least one inorganic material selected from the group consisting of: a metal oxide, especially copper oxide (CuO), especially nickel oxide (NiO), copper iodide (CuI), copper thiocyanate (CuSCN), where the inorganic material may be in crystalline form or may comprise nanoparticles. Other materials are also conceivable in principle. The hole transport layer may also be doped with one of the materials from the group consisting of: Li-TFSI (lithium bis(trifluoromethanesulfonyl)imide), TBP (4-tert-butylpyridine), FK209 (tris[2-(1H-pyrazol-1-yl)-4-tert-butylpyridine]cobalt(III), tris[bis(trifluoromethyl-sulfonyl)imide]), F4-TCNQ (2,3,5,6-tetrafluoro-7,7,8,8-tetracyanoquinodimethane). The hole transport layer may especially comprise a combination of two or more materials. The combination may comprise two or more materials one on top of another and/or two or more materials alongside one another and/or a mixture of two or more materials. The hole transport layer may especially be produced by at least one deposition method selected from the group consisting of: sputtering, electron beam evaporation, thermal evaporation, rotary coating, knife coating, inkjet printing. However, other methods are also conceivable in principle.

The electron transport layer may comprise at least one organic material selected from the group consisting of: PCBM (6,6-phenyl C61 butyric methyl ester), ICBA (indene-C60 bisadduct), C60. In addition, the electron transport layer may comprise at least one inorganic material selected from the group consisting of: a metal oxide, especially tin oxide (SnO₂), especially titanium oxide (TiO2), where the inorganic material may be of crystalline configuration or may comprise nanoparticles. Other materials are also conceivable in principle. The electron transport layer may especially comprise a combination of two or more materials. The combination may comprise two or more materials one on top of another and/or two or more materials alongside one another and/or a mixture of two or more materials. The electron transport layer may especially be produced by at least one deposition method selected from the group consisting of: sputtering, electron beam evaporation, thermal evaporation, rotary coating, knife coating, inkjet printing. However, other methods are also conceivable in principle.

The electron transport layer, the hole transport layer may each have a layer thickness of 0 nm to 500 nm, preferably of 10 nm to 200 nm. However, other dimensions are also conceivable in principle.

In addition, the first layer stack and/or the second layer stack may have one or more buffer layers. The buffer layer may comprise at least one material selected from the group consisting of: bathocuproin (BCP), lithium fluoride (LiF), polyfluorene (PFN). In addition, the buffer layer may comprise at least one inorganic material comprising nanoparticles, for example based on Al₂O₃, ZnO or TiO₂. Other materials are also conceivable in principle. The buffer layer may especially be applied atop the electron transport layer and/or atop the hole transport layer. Other configurations are also conceivable in principle.

In addition, the buffer layer may comprise a material of the hole transport layer or a material of the electron transport layer. The buffer layer may especially comprise at least one material selected from the group consisting of: PCBM (6,6-phenyl C61 butyric methyl ester); ICBA (indene-C60 bisadduct); C60; a metal oxide, especially tin oxide (SnO2), especially titanium oxide (TiO2). The metal oxide may especially be of crystalline configuration or may comprise nanoparticles. In addition, the buffer layer may comprise at least one material selected from the group consisting of: a polymer, PTAA (poly[bis(4-phenyl)(2,4,6-trimethylphenyl)amine]), PEDOT:PSS (poly(cthylenedioxythiophenc):poly(styrene-sulfonate)), Poly-TPD (poly[N,N′-bis(4-butylphenyl)-N,N′-bis(phenyl)benzidine]), P3HT (poly(3-hexylthiophene)). In addition, the buffer layer may comprise at least one material based on small molecules, especially spiro-OMeTAD (2,2′,7,7′-tetrakis(N,N-di-4-methoxyphenylamino)-9,9′-spirobifluorene). In addition, the buffer layer may comprise at least one self-assembly monolayer selected from the group: 2PACz ([2-(9H-carbazol-9-yl)ethyl]phosphonic acid), (7) MeO-2PACz ([2-(3,6-dimethoxy-9H-carbazol-9-yl)ethyl]phosphonic acid. In addition, the buffer layer may comprise at least one inorganic material selected from the group consisting of: a metal oxide, especially copper oxide (CuO), especially nickel oxide (NiO), copper iodide (CuI), copper thiocyanate (CuSCN), where the inorganic material may be in crystalline form or may comprise nanoparticles. Other materials are also conceivable in principle. The buffer layer may additionally have been doped with one of the materials from the group consisting of: Li-TFSI (lithium bis(trifluoromethanesulfonyl)imide), TBP (4-tert-butylpyridine), FK209 (tris[2-(1H-pyrazol-1-yl)-4-tert-butylpyridine]cobalt(III), tris[bis(trifluoromethylsulfonyl)imide]), F4-TCNQ (2,3,5,6-tetrafluoro-7,7,8,8-tetracyanoquinodimethane).

The buffer layer may have a layer thickness of 0 nm to 30 nm, preferably of 10 nm to 20 nm. However, other dimensions are also conceivable in principle.

In addition, the first layer stack and/or the second layer stack may have one or more passivation layers. The passivation layer may comprise at least one material selected from the group consisting of: PEAI/PEABr/PEACl (phenylethylammonium iodide/bromide/chloride), OAI/OABr/OACl (octylammonium iodide/bromide/chloride), BAI/BABr/BACl (butylammonium iodide/bromide/chloride), LiF (lithium fluoride), PMMA (poly(methyl methacrylate)), Al₂O₃ (aluminum oxide), Lewis bases, Lewis acids. Other materials are also conceivable in principle. The passivation layer may be applied, for example, atop the electron transport layer and/or atop the hole transport layer. Other configurations are also conceivable in principle. The passivation layer may be used for surface functionalization.

This fundamentally alters chemical properties of the adjoining layer. The passivation layer may especially be produced by at least one deposition method selected from the group consisting of: rotary coating, thermal evaporation, sputtering, electron beam evaporation, knife coating, inkjet printing. However, other methods are also conceivable in principle.

The passivation layer may have a layer thickness of 1 nm to 10 nm, preferably of 2 nm to 5 nm.

As set out above, in step c), the first layer stack is applied to the second layer stack. The term “applying” in this connection refers to layering of the two layer stacks one on top of another.

The first layer stack may have a first concluding layer. The second layer stack may have a second concluding layer. The expression “concluding layer” in principle relates to any layer of a layer stack or a layer construction comprising multiple mutually superposed layers that adjoins an external environment of the layer stack or the layer construction by a longitudinal side of the layer. In step c), the first layer stack may be applied to the second layer stack in such a way that the first concluding layer of the first layer stack and the second concluding layer of the second layer stack adjoin one another. With regard to the expression “adjoin one another”, reference is made analogously to the definition of the term “mutually superposed” above.

The perovskite layer may form the first concluding layer, and the electron transport layer or the hole transport layer may form the second concluding layer. This may also be reversed, i.e. the perovskite layer may form the second concluding layer and the electron transport layer or the hole transport layer may form the first concluding layer. In addition, the first concluding layer or the second concluding layer may each be buffer layers.

It is possible for the first layer and/or the second layer to be applied to further layers of the first layer stack or of the second layer stack. The first layer and/or the second layer therefore need not necessarily be applied to the perovskite layer. By means of the lamination, it is possible in principle to apply the first layer and/or the second layer to the perovskite layer. It is possible in principle to produce inorganic hole transport layers and/or electron transport layers from a vacuum phase. There may be a high level of quality here, with compact characteristics. This is basically impossible, or possible only to a limited degree, with materials from the liquid phase that use nanoparticles, for example, and hence always produce porous layers. Compact layers may in principle contribute to stability of the component architecture. In addition, the perovskite layer may be applied atop the first layer and/or atop the second layer. However, other designs are also conceivable.

As set out above, in step d), the first layer stack is laminated onto the second layer stack. The term “laminating” refers in principle to any cohesive thermal method of joining at least two elements, especially without further auxiliary materials such as adhesives. The two elements may be introduced into a hot press one on top of the other, and the joining method may be executed under the action of temperature and pressure. In the context of the present invention, the term “laminating” especially refers to any cohesive thermal method of joining the first concluding sight of the first layer stack to the second concluding layer of the second layer stack. The term “mechanical connection” refers in principle to a connection between two or more elements in such a way that parting of the two or more elements in proper operation of the elements is prevented. The term “electrical connection” refers in principle to a connection between two or more elements in such a way that electrical contact is established between the elements, meaning that a charge carrier can be transported between the elements via a contact region. During step d), it is also possible in principle for more than two layer stacks to be laminated to one another. In particular, the first layer stack and the second layer stack may be laminated to at least one further layer stack, especially at least one third layer stack, during step d).

For the lamination, the first layer stack and the second layer stack may be introduced into a hot press. Under action of pressure and temperature, the perovskite layer can recrystallize with the result of mechanical and electrical connection between the first layer stack and the second layer stack. The hot press may have a first plate and a second plate. The first plate and the second plate can first be heated at a hold pressure, especially of 5 MPa to 20 MPa. On attainment of a process temperature, the pressure can be increased to a process pressure. The process temperature may especially be between 50° ° C. and 300° C., especially between 60° C. and 150° C. The process pressure may especially be between 10 MPa and 250 MPa, especially between 20 MPa and 150 MPa. The process can especially be effected over a period of 1 s to 2 h, especially of 5 min to 30 min. For example, step d) can be effected at a process temperature of 90° C., at a process pressure of 80 MPa and for a duration of 10 min. Subsequently, the perovskite-based multi-junction solar cell can be cooled down and the pressure dissipated. The sequence here may vary. For example, the perovskite-based multi-junction solar cell may first be cooled down and then the pressure can be dissipated. Alternatively, the pressure can first be dissipated and then the perovskite-based multi-junction solar cell can be cooled down.

As set out above, the perovskite layer forms the laminate-forming layer either of the first layer stack or of the second layer stack. The expression “laminate-forming layer” refers in principle to a layer of the first layer stack which is cohesively bonded to a layer of the second layer stack under the action of temperature and pressure. In addition, the expression “laminate-forming layer” may refer to a layer of the second layer stack which is cohesively bonded to a layer of the first layer stack under the action of temperature and pressure. In a first working example, the perovskite layer may form the laminate-forming layer of the first layer stack, and the laminate-forming layer of the second layer stack may not be a perovskite layer. In a second working example, the perovskite layer may form the laminate-forming layer of the second layer stack, and the laminate-forming layer of the first layer stack may not be a perovskite layer. In particular, the laminate-forming layer may be the first concluding layer of the first layer stack or the second concluding layer of the second layer stack. In addition, the laminate-forming layer may be the first concluding layer of the first layer stack or the second concluding layer of the second layer stack and may comprise a surface treatment. Alternatively, a further layer may have been applied atop the perovskite layer. The further layer may especially be selected from the group consisting of: a buffer layer, a passivation layer. Further working examples are also conceivable in principle. In particular, the perovskite layer may be a layer selected from the group consisting of: the first concluding layer of the first layer stack; the second concluding layer of the second layer stack; a layer of the first layer stack adjoining the first concluding layer; a layer of the second layer stack adjoining the second concluding layer. The layer of the first layer stack adjoining the first concluding layer and the layer of the second layer stack adjoining the second concluding layer may also be referred to as layers beneath the first and second concluding layers. The first layer stack and/or the second layer stack may additionally optionally comprise further perovskite layers.

By multiple lamination, the perovskite-based multi-junction solar cell may be produced in a monolithic (n+1)-terminal interconnection, where n is a number of absorber layers. It is thus possible to produce a series interconnection with (n+1) contacts. Contact connection and/or interconnection of each electrode or between electrodes can be effected by displacement of the layer stacks. Other approaches are also conceivable in principle.

Prior to performance of step d), the perovskite in the perovskite layer may be in the solid phase. The term “phase” refers here to a state of matter of a substance that can be transformed to a different state of matter by a mere change in temperature and/or pressure. The perovskite layer may therefore be a solid layer. In addition, further layers of the first layer stack, especially the first electrode and/or the first layer, and/or further layers of the second layer stack, especially the second electrode, and/or the absorber layer, and/or the recombination layer and/or the buffer layer and/or the second layer, may be in the solid phase prior to performance of step d). During step d), connection between the first layer stack and the second layer stack can be effected by recrystallizing the solid perovskite layer. Steps a) to d) may be adhesive-free method steps. The expression “adhesive-free method step” refers in principle here to a method step which is effected without use or application of any adhesive. It is possible to dispense with use of an additional adhesive as an addition in other layers of the stack as well. In this way, it is possible to dispense with an additional adhesive layer. In the perovskite-based multi-junction solar cell, there may especially be solely optical and electrical functional layers. Additional optical, mechanical and/or electrical losses can therefore fundamentally be avoided. This may in principle lead to a high stability of the perovskite-based multi-junction solar cell. In addition, it is possible in principle to increase the efficiency of the perovskite-based multi-junction solar cell. The method of the invention may thus be a scalable process since no liquid phase is present in the bonding of the first layer stack to the second layer stack. In addition, the component structure may be a simple one. Production costs can in principle be reduced.

By means of the method of the invention, production of perovskite-based multi-junction solar cells is possible in principle with different configurations. The method of the invention enables novel configurations of the first layer stack and/or of the second layer stack, as are fundamentally unobtainable by existing methods.

The laminating can produce electron transport layers and/or hole transport layers composed of compact and/or coherent layers as well. In particular, the layers may be nonporous layers. In particular, the layers may not be nano- and/or microparticle-based layers. It is especially possible to produce combinations including perovskite, an electron transport layer comprising at least one material selected from the group consisting of: SnO₂, TiO₂, cadmium-selenium quantum dots (CdₓSe_{y}), tungsten oxide (WₓO_{y}), strontium titanate (SrTiO₃), tin oxide (ZnO), and a hole transport layer comprising at least one further material selected from the group consisting of: nickel oxide (NiOₓ), (copper oxide) Cu₂O, copper thiocyanate (CuSCN), copper oxide (CuOₓ), copper chromium oxide (Cu:CrOₓ), molybdenum(VI) oxide (MoO₃), vanadium oxide (VₓO_{y}), nickel phthalocyanine (NiPc).

New degrees of freedom are thus possible in principle in the process sequence of the production method. In addition, faster production process sequences are possible in principle. Furthermore, it is possible in principle to achieve lower process temperatures or low energy use, mechanically stable components and/or stable component architectures.

The perovskite layer may have a layer thickness of 800 nm to 10 μm, especially of 1 μm to 5 μm. In addition, the perovskite layer may have a layer thickness of 50 nm to 800 nm, especially of 500 nm to 600 nm. By means of a thick perovskite layer, it is possible to balance out a texture or a roughness on an upper face of the absorber layer and to ensure at least virtually complete coverage. The perovskite layer can adapt to the texture of the absorber layer here and may have a defined/controlled texture on a side remote from the texture of the absorber layer, for example a planar, a rough or a structured texture. It is possible to apply a thick perovskite layer atop the first layer stack or atop the second layer stack, which adapts to the texture of the absorber layer at least virtually without defects in the lamination process. This is fundamentally impossible by other methods. It is thus possible to increase a luminous efficacy and/or an angle-dependent luminous efficacy and hence the efficiency of the perovskite-based multi-junction solar cell.

In addition, a layer stack may in principle be laminated repeatedly. In particular, a layer stack may be laminated repeatedly onto another layer stack. For this purpose, it is possible to use a substrate, for example a planar silicon wafer, a planar glass, or another substrate, on which, for example, a nonstick layer of polydimethylsiloxane (PDMS), polytetrafluoroethylene (PTFE), FTO, ITO, SnO₂, NiOₓ may be applied. Also possible in principle are further layers from which the layer stack can be detached again from the nonstick layer as a unit after lamination. By multiple lamination of a layer stack onto a further layer stack, it is possible to produce a multi-junction solar cell that may have more than two absorber layers, for example.

The perovskite layer may take the form of a planar layer. In particular, it is possible to create a planar form of the perovskite layer by laminating a detachable layer onto the perovskite layer. It is thus possible to avoid a limitation in the processing of the multi-junction solar cell that arises from a rough perovskite layer.

The perovskite-based multi-junction solar cell may especially have more than two absorbers. The perovskite-based multi-junction solar cell having more than two absorbers may especially have more than two layer stacks that are laminated to one another. It is thus possible to increase an efficiency of the perovskite-based multi-junction solar cell. In particular, the perovskite-based multi-junction solar cell may have more than two absorbers. Other configurations are also conceivable in principle. For example, the perovskite-based multi-junction solar cell may have three absorbers, a perovskite layer, a first absorber layer and a second absorber layer. The first and/or second absorber layers may comprise a material selected from the group consisting of: perovskite, crystalline or amorphous silicon, copper-indium-gallium diselenide (CIGS), cadmium telluride (CdTe), gallium arsenide (GaAs), germanium (Ge), indium gallium arsenide (InGaAs), indium gallium phosphide (InGaP). Other materials are also conceivable in principle. The layer stacks may in particular be disposed one on top of another.

In a further aspect, a perovskite-based multi-junction solar cell is proposed. The perovskite-based multi-junction solar cell comprises at least one first layer stack. The first layer stack has at least one first electrode and at least one first layer. In addition, the first layer stack may have at least one substrate. Furthermore, the perovskite-based multi-junction solar cell comprises at least one second layer stack. The second layer stack has at least one absorber layer and at least one second layer. In addition, the second layer stack may have at least one second electrode. Furthermore, the second layer stack may have a recombination layer. The first layer stack has been applied to the second layer stack. The first layer stack has been laminated onto the second layer stack in such a way that at least one connection selected from the group consisting of: a mechanical connection, an electrical connection between the first layer stack and the second layer stack has been formed. The first layer and the second layer are each selected from the group consisting of: a hole transport layer, an electron transport layer, a buffer layer, a recombination layer, an electrode layer. The first layer stack or the second layer stack has a perovskite layer. The perovskite layer forms a laminate-forming layer either of the first layer stack or of the second layer stack.

The perovskite-silicon multi-junction solar cell is producible by the method of producing a perovskite-based multi-junction solar cell as already described or still to be described below. For further details of configurations and designs of the perovskite-silicon multi-junction solar cell, reference may therefore be made analogously to the above description, and that which follows, of the method of producing a perovskite-based multi-junction solar cell.

In one working example of the perovskite-based multi-junction solar cell, the first layer stack may comprise the first electrode. In particular, the first electrode may have been applied atop the substrate. In particular, the substrate may comprise glass, especially flexible glass. In particular, the substrate may have a thickness of 50 μm to 5 mm, especially of 100 μm to 250 μm. In particular, the first electrode may comprise indium tin oxide (ITO). In particular, the first electrode may have a thickness of 100 nm to 500 nm, especially of 120 nm to 300 nm. In addition, the second layer stack in the working example may comprise a further substrate, the second electrode, the absorber layer, and the second layer, which is a recombination layer. The further substrate may comprise glass. In particular, the further substrate may have a thickness of 50 μm to 5 mm, especially of 1 mm. The second electrode may especially comprise molybdenum (Mo). The second electrode may have a thickness of 0.1 μm to 2 μm, especially of 0.2 μm to 1 μm. In particular, the absorber layer may comprise a copper-indium-gallium diselenide (CIGS) solar cell. The CIGS solar cell may especially have a thickness of 1 μm to 5 μm. A surface of the CIGS solar cell may especially have a root mean square roughness of 1 nm to 2 μm. The surface may especially be a surface remote from the further substrate. The second layer, especially the recombination layer, may especially lie on the surface of the CIGS solar cell. The second layer may have a thickness of 1 μm to 5 μm. The recombination layer may especially comprise indium tin oxide (ITO). The recombination layer may especially have a thickness of 15 nm to 100 nm, especially of 30 nm to 70 nm.

In the working example of the perovskite-based multi-junction solar cell, the first layer stacks and the second layer stacks may additionally each comprise further layers, especially at least one perovskite layer, especially having a thickness of 100 nm to 2 μm, especially of 300 nm to 800 nm, at least one hole transport layer and/or at least one electron transport layer. The hole transport layer may especially comprise nickel oxide (NiOₓ). The hole transport layer composed of nickel oxide (NiOₓ) may especially have a thickness of 10 nm to 50 nm, especially of 20 nm to 30 nm. In addition, the hole transport layer may especially comprise a self-assembly monolayer, especially 2PACz ([2-(9H-carbazol-9-yl)ethyl]phosphonic acid). The hole transport layer composed of 2PACz may especially lie atop the hole transport layer composed of nickel oxide and hence form a double hole transport layer. The electron transport layer may especially comprise tin oxide (SnOₓ) and especially have a thickness of 10 nm to 50 nm, especially of 30 nm to 40 nm. In addition, the electron transport layer may especially comprise fullerene (C60) and especially have a thickness of 10 nm to 30 nm, especially of 20 nm to 25 nm. The electron transport layer composed of tin oxide may especially lie atop the electron transport layer composed of fullerene and hence form a double electron transport layer.

For example, in the working example of the perovskite-based multi-junction solar cell, the first layer stack may comprise the hole transport layer and the perovskite layer. The hole transport layer may especially lie atop the first electrode. The perovskite layer may especially lie atop the hole transport layer. The second layer stack may comprise the electron transport layer. The electron transport layer may especially lie atop the recombination layer.

Alternatively, in the working example of the perovskite-based multi-junction solar cell, the first layer stack may comprise the electron transport layer and the perovskite layer. The electron transport layer may especially lie atop the first electrode. The perovskite layer may especially lie atop the electron transport layer. The second layer stack may comprise the hole transport layer. The hole transport layer may especially lie atop the recombination layer.

Alternatively, in the working example of the perovskite-based multi-junction solar cell, the first layer stack may comprise the hole transport layer. The hole transport layer may especially lie atop the first electrode. The second layer stack may comprise the electron transport layer and the perovskite layer. The electron transport layer may especially lie atop the recombination layer. The perovskite layer may especially lie atop the electron transport layer.

Alternatively, in the working example of the perovskite-based multi-junction solar cell, the first layer stack may comprise the electron transport layer. The electron transport layer may especially lie atop the first electrode. The second layer stack may comprise the hole transport layer and the perovskite layer. The hole transport layer may especially lie atop the recombination layer. The perovskite layer may especially lie atop the hole transport layer.

Alternatively, in the working example of the perovskite-based multi-junction solar cell, the first layer stack may comprise the hole transport layer and the perovskite layer. The hole transport layer may especially lie atop the first electrode. The perovskite layer may especially lie atop the hole transport layer. The second layer stack may comprise the electron transport layer and a further perovskite layer. The electron transport layer may especially lie atop the recombination layer. The further perovskite layer may especially lie atop the electron transport layer.

Alternatively, in the working example of the perovskite-based multi-junction solar cell, the first layer stack may comprise the electron transport layer and the perovskite layer. The electron transport layer may especially lie atop the first electrode. The perovskite layer may especially lie atop the electron transport layer. The second layer stack may comprise the hole transport layer and the further perovskite layer. The hole transport layer may especially lie atop the recombination layer. The further perovskite layer may especially lie atop the hole transport layer.

Alternatively, in the working example of the perovskite-based multi-junction solar cell, the first layer stack may comprise the hole transport layer. The hole transport layer may especially lie atop the first electrode. The second layer stack may comprise the electron transport layer, the perovskite layer and the further perovskite layer. The electron transport layer may especially lie atop the recombination layer. The perovskite layer may especially lie atop the electron transport layer. The further perovskite layer may especially lie atop the perovskite layer. The perovskite layer and the further perovskite layer may especially be applied successively by sequential lamination.

Alternatively, in the working example of the perovskite-based multi-junction solar cell, the first layer stack may comprise the electron transport layer. The electron transport layer may especially lie atop the first electrode. The second layer stack may comprise the hole transport layer, the perovskite layer and the further perovskite layer. The hole transport layer may lie atop the recombination layer. The perovskite layer may especially lie atop the hole transport layer. The further perovskite layer may especially lie atop the perovskite layer.

In a further working example of a perovskite-based multi-junction solar cell, the first layer stack may comprise the substrate, the first electrode, two first layers and the perovskite layer. In particular, the first electrode may have been applied atop the substrate. In particular, the two first layers may have been applied atop the first electrode. In particular, the perovskite layer may have been applied atop the two first layers. The two first layers may especially be electron transport layers, especially two essentially mutually superposed electron transport layers.

The substrate may especially comprise polyethylene naphthalate (PEN). In particular, the substrate may be or comprise a film of polyethylene naphthalate (PEN). The substrate may especially have a thickness of 125 μm. The first electrode may especially comprise indium tin oxide (ITO). The first electrode may especially have a thickness of 300 nm.

The two first layers may especially be two electron transport layers, especially a first electron transport layer and a second electron transport layer. The first electron transport layer may especially comprise tin oxide (SnOₓ). The first electron transport layer may especially have a thickness of 35 nm. The second electron transport layer may especially comprise fullerene (C60). The second electron transport layer may especially have a thickness of 20 nm.

The perovskite layer may especially comprise Cs_{0.1}(MA_{0.17}FA_{0.83})_{0.9}Pb(I_{0.83}Br_{0.17})₃. The perovskite layer may especially have a thickness of 370 nm.

The second layer stack may especially comprise the second electrode, the absorber layer, and three second layers. The absorber layer in particular may have been applied atop the second electrode. The three second layers in particular may have been applied atop the absorber layer. The three second layers may especially be two hole transport layers and one recombination layer, especially three essentially mutually superposed second layers.

The second electrode may especially comprise indium tin oxide (ITO). The second electrode may especially have a thickness of 70 nm.

The absorber layer may especially comprise a silicon solar cell. The silicon solar cell may especially have the following architecture: a-Si:H<n>/a-Si:H<i>/c-Si wafer <n>/a-Si:H<i>/a-Si:H<p>. The junction may be a heterojunction. The silicon solar cell may especially have been polished on both sides. The silicon solar cell may especially have a thickness of 280 μm.

The recombination layer in particular may lie atop the absorber layer. The recombination layer may especially comprise indium tin oxide (ITO). The recombination layer may especially have a thickness of 30 nm.

The two hole transport layers in particular may lie atop the recombination layer, especially a first hole transport layer and a second hole transport layer. The first hole transport layer may especially lie atop the recombination layer, and the second hole transport layer may especially lie atop the first hole transport layer. The first hole transport layer may especially comprise nickel oxide (NiOₓ). The first hole transport layer may especially have a thickness of 20 nm. The second hole transport layer may especially comprise a self-assembly monolayer, especially 2PACz ([2-(9H-carbazol-9-yl)ethyl]phosphonic acid).

In a further working example of the perovskite-based multi-junction solar cell, the substrate may have been produced from glass. The substrate may have a thickness of 1 mm. The first electrode may comprise indium tin oxide. The first electrode may have a thickness of 100 nm or of 150 nm. The electron transport layer may comprise tin oxide (SnO₂). The electron transport layer may comprise a thickness of 10 nm or of 20 nm. The perovskite layer may have a thickness of 350 nm or of 700 nm. The hole transport layer may comprise PTAA (poly[bis(4-phenyl)(2,4,6-trimethylphenyl)amine]) and have a thickness of 5 nm or of 10 nm. The perovskite-based multi-junction solar cell may have a further hole transport layer. The further hole transport layer may comprise nickel oxide (NiOₓ). The further hole transport layer may have a thickness of 10 nm or of 20 nm. The recombination layer may comprise indium tin oxide. The recombination layer may have a thickness of 15 nm or of 70 nm. In addition, the perovskite-based multi-junction solar cell may comprise a silicon solar cell. The silicon solar cell may have a thickness of 200 μm or of 300 μm.

In a further working example of the perovskite-based multi-junction solar cell, the substrate may have been produced from glass. The substrate may have a thickness of 1 mm. The first electrode may comprise indium tin oxide. The first electrode may have a thickness of 100 nm. The electron transport layer may comprise tin oxide (SnO₂). The electron transport layer may have a thickness of 10 nm. The perovskite layer may have a thickness of 350 nm. The hole transport layer may comprise nickel oxide (NiOₓ). The hole transport layer may have a thickness of 10 nm. The recombination layer may comprise indium tin oxide. The recombination layer may have a thickness of 15 nm. In addition, the perovskite-based multi-junction solar cell may comprise a silicon solar cell. The silicon solar cell may have a thickness of 200 μm. The perovskite-based multi-junction solar cell may have a further recombination layer. The further recombination layer may comprise indium tin oxide. The further recombination layer may have a thickness of 15 nm. The perovskite-based multi-junction solar cell may comprise the further hole transport layer. The further hole transport layer may comprise PTAA (poly[bis(4-phenyl)(2,4,6-trimethylphenyl)amine]). The further hole transport layer may have a thickness of 5 nm. The perovskite-based multi-junction solar cell may have an absorber layer. The absorber layer may comprise perovskite. The absorber layer may have a thickness of 300 nm. The perovskite-based multi-junction solar cell may have a further electron transport layer. The further electron transport layer may comprise tin oxide (SnO₂). The further electron transport layer may have a thickness of 10 nm. The second electrode may comprise indium tin oxide. The second electrode may have a thickness of 100 nm. The perovskite-based multi-junction solar cell may have a further substrate. The further substrate may have been produced from polyethylene naphthalate. The further substrate may have a thickness of 125 μm.

The devices proposed and the methods proposed have numerous advantages over known devices and methods.

For instance, material incompatibilities can be reduced in principle, and it is possible in principle to gain a degree of freedom in the choice of the production processes for the individual layers. A limitation in selection of the charge transport layers, electrodes and recombination layer through sequential production can be dispensed with. It is possible to laminate the perovskite absorber of the perovskite solar cell onto a silicon solar cell and hence to produce a tandem perovskite-silicon solar cell. It is possible to incorporate significantly more robust and more stable oxide charge carrier transport layers into the two separate layer stacks. An increased selection of materials of further charge carrier transport layers and of electrode layers, buffer layers, passivation layers, contact layers and/or encapsulation layers may also be enabled. Electrode layers, buffer layers and/or passivation layers may in principle be processed at higher temperatures beneath the perovskite layer of the first layer stack and/or of the second layer stack. Properties of the electrode layers, buffer layers and/or passivation layers that are processed at higher temperatures may in principle be improved by comparison with electrode layers, buffer layers and/or passivation layers that are processed at lower temperatures on a layer stack. It is additionally possible in principle to achieve improved long-term stability of perovskite-based multi-junction solar cells.

The lamination method is particularly suitable in principle for upscaling processes, for example roll-to-roll manufacture. In addition, parallelization can be achieved by the separate production of the layer stacks. The greater material selection in particular brings a greater selection of possible processes for production of the layers. The lamination increases the process selection. Use of materials in the solid phase, especially during the laminating, enables scalable processes in principle. Homogeneity problems in liquid phase processes can thus be avoided. Multi-junction solar cells can be produced inexpensively in principle with simultaneous, high throughput.

Lamination enables novel solar cell architectures in principle. This opens up the possibility of higher efficiencies and improved stability in principle.

The fact that the perovskite layer forms a laminate-forming layer either of the first layer stack or of the second layer stack leads in principle to a free material selection for the perovskite-based multi-junction solar cell and to a free selection of the deposition methods for the deposition of the hole transport layer, the electron transport layer, the buffer layer, the recombination layer or the electrode. In principle, it is possible to apply a charge carrier-selective layer, especially the hole transport layer or the electron transport layer, and an electrode/recombination layer to the perovskite layer. By virtue of the laminating, it is possible to produce the layers required in advance in terms of time and/or beneath the perovskite layer in terms of space. This can in principle minimize incompatibilities and increase a selection of possible materials and/or production methods for the layers of the perovskite-based multi-junction solar cell. In addition, the material selection of the further laminate-forming layer can in principle be increased since it does not necessarily have to be produced atop the perovskite layer but can be applied atop in each case one of the layer stacks to be laminated.

### EMBODIMENTS OF THE INVENTION

Further optional details and features of the invention will be apparent from the description of preferred working examples that follows. The figures show:

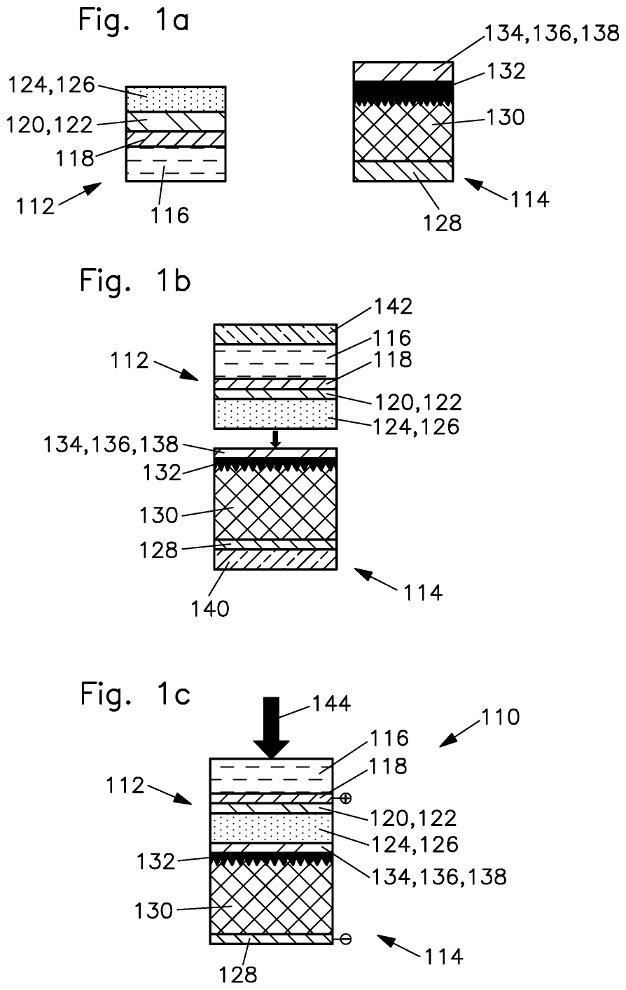

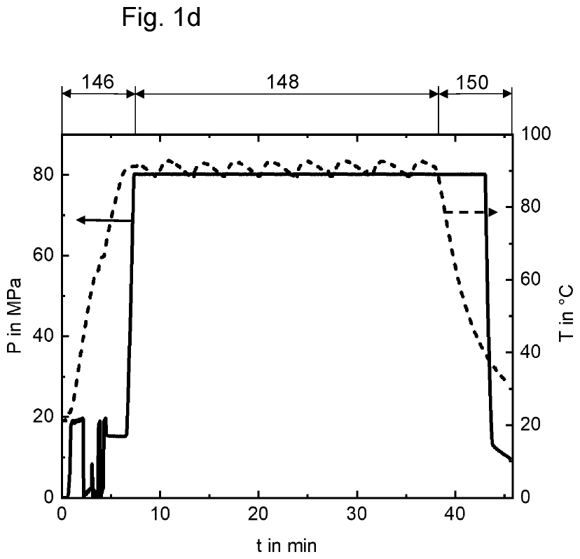

FIGS. 1A to 1D a method of the invention for production of a perovskite-based multi-junction solar cell;

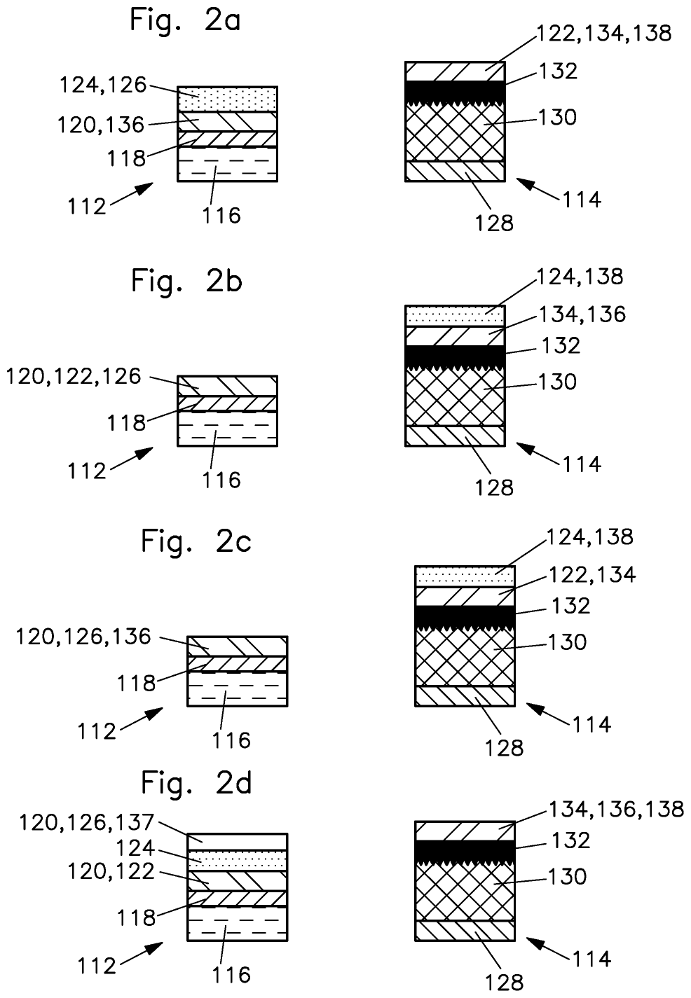

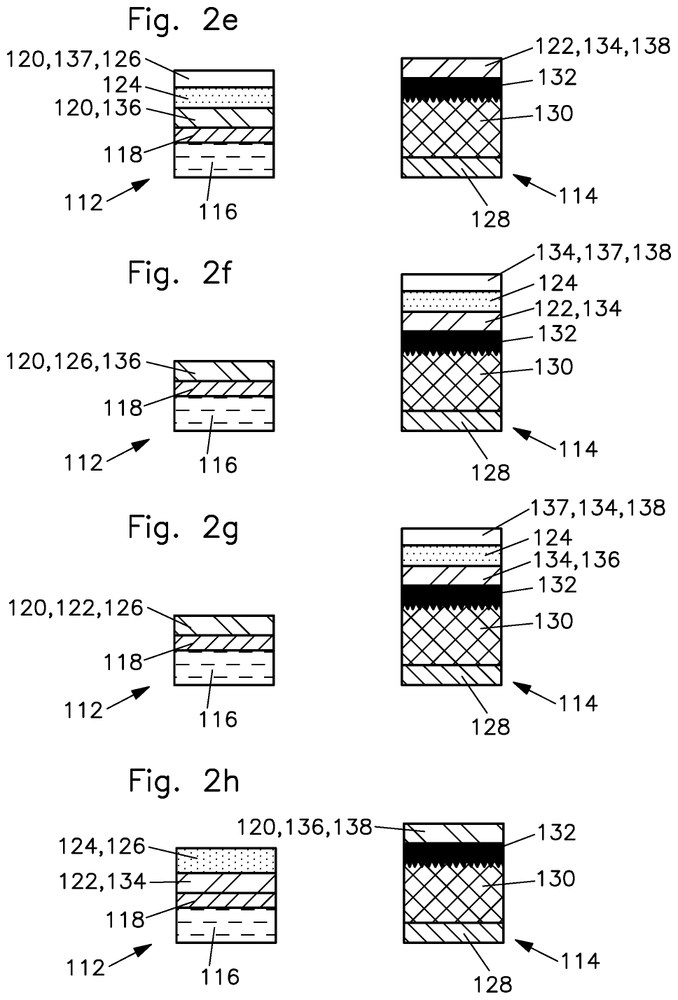

FIGS. 2A to 2H illustrative working examples of the first layer stack and of the second layer stack;

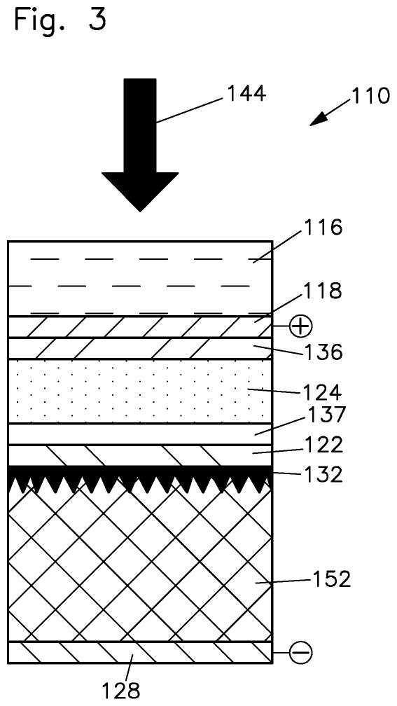

FIG. 3 an illustrative working example of a perovskite-based multi-junction solar cell;

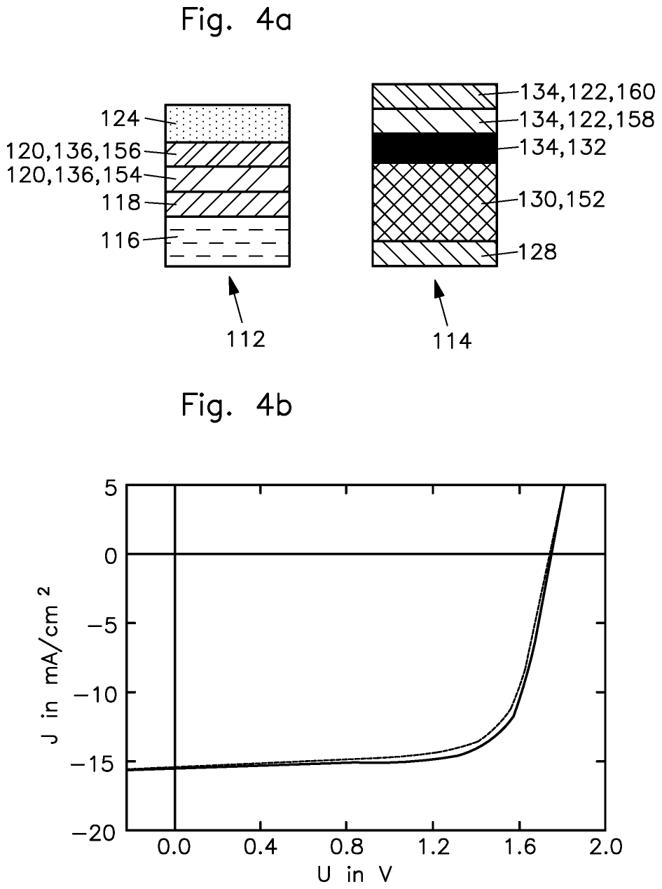

FIGS. 4A and 4B a further illustrative working example of a first layer stack and of a second layer stack of a perovskite-based multi-junction solar cell (FIG. 4A) and measurement data for the illustrative working example (FIG. 4B); and

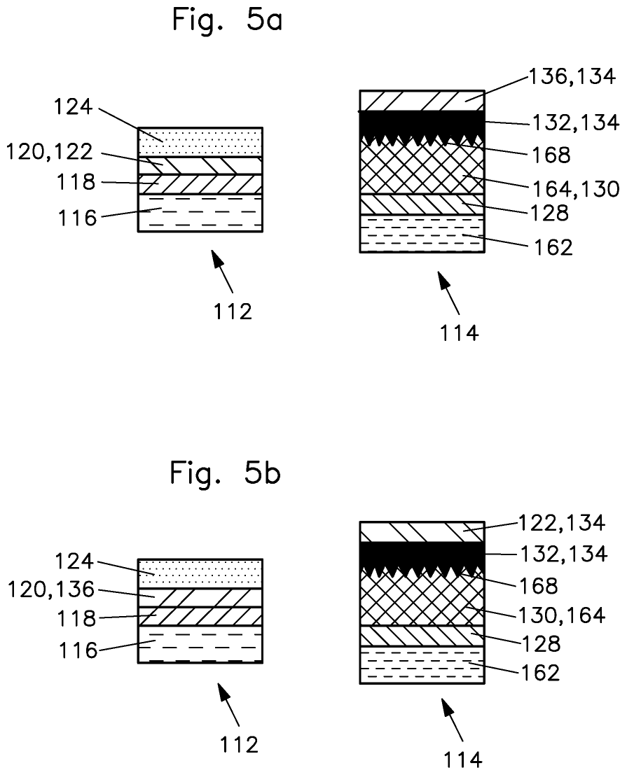

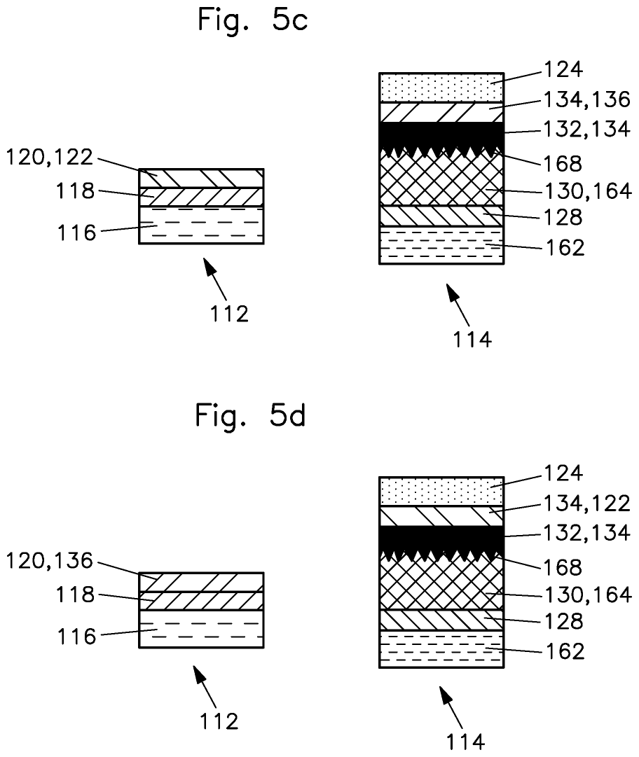

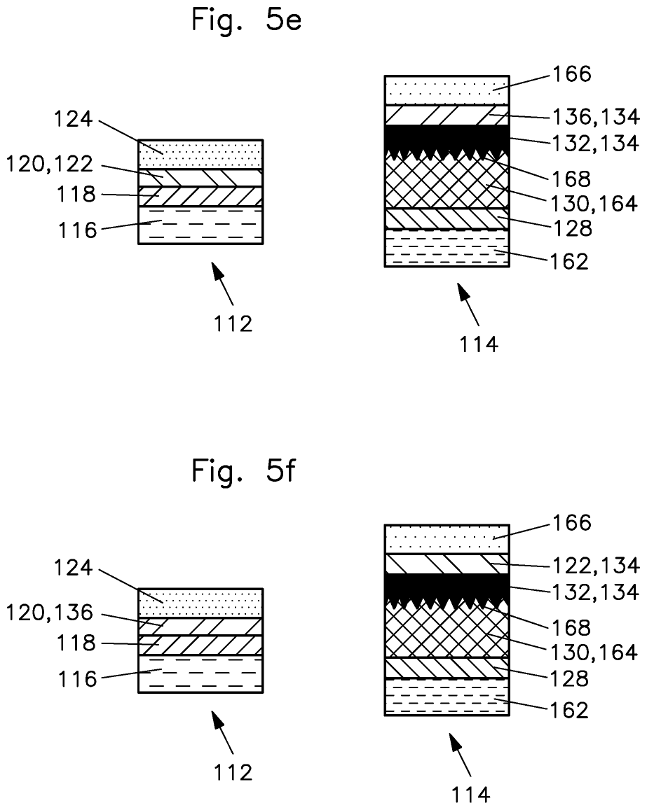

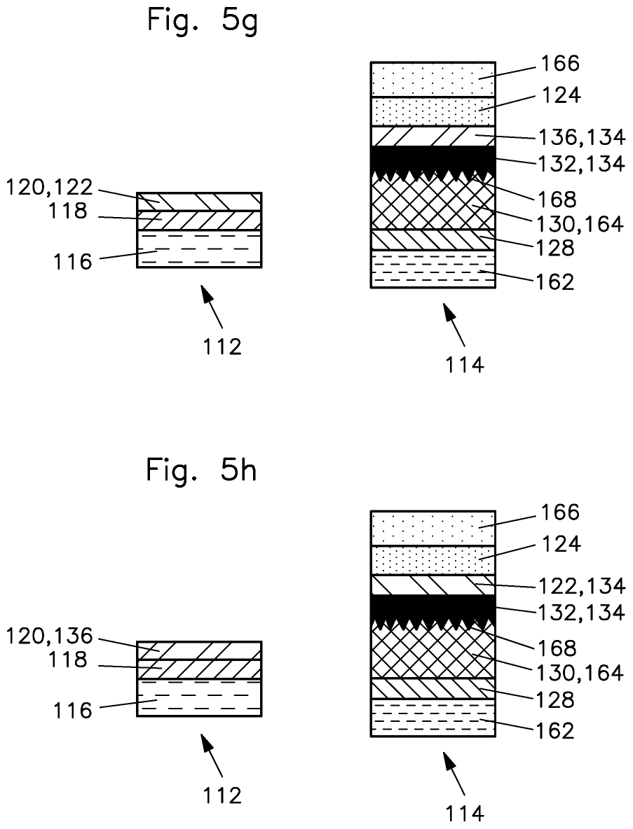

FIGS. 5A to 5H further illustrative working examples of a first layer stack and a second layer stack of a perovskite-based multi-junction solar cell.

FIGS. 1A to 1D show a method of the invention for production of a perovskite-based multi-junction solar cell 110. The perovskite-based multi-junction solar cell 110 is shown in FIG. 1C. FIG. 1A shows a first layer stack 112 and a second layer stack 114. FIG. 1B shows the laminating of the first layer stack 112 and of the second layer stack 114, and FIG. 1D shows an illustrative example of process parameters in a graph.

The first layer stack 112, as shown in FIG. 1A, has been applied atop a substrate 116. The first layer stack 112 has a first electrode 118 which may take the form of a layer atop the substrate 116. In addition, the first layer stack 112 has a first layer 120. The first layer 120 may be formed atop the first electrode 118. In this working example, the first layer 120 may be a hole transport layer 122. In addition, in this working example, the first layer stack 112 may have a perovskite layer 124. The perovskite layer 124 may form a first concluding layer 126 of the first layer stack 112.

The second layer stack 114 may have a second electrode 128. In addition, the second layer stack 114 has an absorber layer 130. The absorber layer 130 may be formed atop the second electrode 128. In addition, the second layer stack 114 has a recombination layer 132. The recombination layer 132 may be formed atop the absorber layer 130. In addition, the second layer stack 114 has a second layer 134. In this working example, the second layer 134 may be an electron transport layer 136. The second layer 134 may be formed atop the recombination layer 132. The second layer 134 may form a second concluding layer 138 of the second layer stack 114.

As shown in FIG. 1B, for the lamination, the first layer stack 112 and the second layer stack 114 may be introduced into a hot press. The first layer stack 112 and the second layer stack 114 may be placed one on top of the other such that the first concluding layer 126 of the first layer stack 112 and the second concluding layer 138 of the second layer stack 114 lie atop one another. FIG. 1B shows a lower plate 140 and an upper plate 142 of the hot press. Under pressure and temperature, the perovskite layer can recrystallize, and a mechanical and electrical connection can form between the first layer stack 112 and the second layer stack 114.

FIG. 1C shows the perovskite-based multi-junction solar cell 110. Incident light is shown schematically by arrow 144.

FIG. 1D shows an illustrative graph of the process parameters of temperature T in ° ° C. and pressure in MPa as a function of time t in min. The method can be divided into three phases. In a heating phase 146, the temperature can rise. In a lamination phase 148 in which the recrystallization of the perovskite layer takes place, the temperature can be kept essentially constant. At the start of the lamination phase 148, a pressure rise can occur. In a cooling phase 150, the temperature can drop continuously. During the cooling phase 150, the pressure can be lowered.

FIGS. 2A to 2H show illustrative working examples of the first layer stack 112 and of the second layer stack 114. The first layer stack 112 and the second layer stack 114 correspond at least partly to the first layer stack 112 and the second layer stack 114 according to FIG. 1A, and so reference may be made to the description of FIG. 1A above.

The first layer stack 112 in FIG. 2A has the electron transport layer 136, and the second layer stack 114 has the hole transport layer 122. The hole transport layer 122 forms the second concluding layer 138. The perovskite layer 124 forms the first concluding layer 126.

In FIG. 2B, the second layer stack 114 has the perovskite layer 124. The perovskite layer 124 forms the second concluding layer 138. In the first layer stack 112, the hole transport layer 122 forms the first concluding layer 126. The electron transport layer 136 forms the first concluding layer 126.

The first layer stack 112 and the second layer stack 114 according to FIG. 2C correspond at least largely to the first layer stack 112 and the second layer stack 114 according to FIG. 2B. Here, the first layer 120 is the electron transport layer 136 and the second layer 134 is the hole transport layer 122.

In the working example according to FIG. 2D, the second layer 134 is the electron transport layer 136 that forms the second concluding layer 138. The first layer stack 112 has two first layers 120, an inner hole transport layer 122 and a buffer layer 137. The buffer layer 137 is disposed atop the perovskite layer 124 and forms the first concluding layer 126.

The first layer stack 112 and the second layer stack 114 according to FIG. 2E correspond at least largely to the first layer stack 112 and the second layer stack 114 according to FIG. 2D. Here, the second concluding layer 138 is the hole transport layer 122. The first layer stack 112 has two first layers 120, an inner electron transport layer 136 and the buffer layer 137. The buffer layer 137 is disposed atop the perovskite layer 124 and forms the first concluding layer 126.

In the working example according to FIG. 2F, the first layer stack 112 has the electron transport layer 136. The second layer stack 114 has the perovskite layer 124 and two second layers 134, an inner hole transport layer 122 and the buffer layer 137. The buffer layer 137 forms the second concluding layer 138.

The first layer stack 112 and the second layer stack 114 according to FIG. 2G correspond at least largely to the first layer stack 112 and the second layer stack 114 according to FIG. 2F. Here, the first layer 120 is the hole transport layer 122. The second layer stack 114 has the perovskite layer 124 and two second layers 134, an inner electron transport layer 136 and the buffer layer 137. The buffer layer 137 forms the second concluding layer 138.

The first layer stack 112 in FIG. 2H has the hole transport layer 122, and the second layer stack 114 has the electron transport layer 136. The electron transport layer 136 forms the second concluding layer 138. The perovskite layer 124 forms the first concluding layer 126.

FIG. 3 shows an illustrative working example of a perovskite-based multi-junction solar cell 110. The perovskite-based multi-junction solar cell 110 has a second electrode 128 of silver having a thickness of 100 nm. The second electrode 128 has been applied beneath a silicon solar cell 152. The silicon solar cell 152 may have a thickness of about 300 μm. An ITO layer having a layer thickness of 70 nm (not shown in FIG. 3) may be present between the second electrode 128 and the silicon solar cell 152. The recombination layer 132 having a thickness of 70 nm has been applied atop the silicon solar cell 152. Alternatively, the recombination layer 132 may have a thickness of 35 nm. The recombination layer 132 may comprise indium tin oxide. A hole transport layer 122 has been applied atop the recombination layer 132, composed of nickel oxide having a thickness of 20 nm. A further hole transport layer 122 has been applied atop the hole transport layer 122, composed of poly[bis(4-phenyl)(2,4,6-trimethylphenyl)amine] having a thickness of less than 10 nm. Alternatively, the further hole transport layer 122 may comprise 2PACz ([2-(9H-carbazol-9-yl)ethyl]phosphonic acid). The perovskite layer 124 has been applied atop the further hole transport layer 122, with a thickness of 370 nm. The electron transport layer 136 of tin oxide has been applied atop the perovskite layer 124, with a thickness of 20 nm. The first electrode 118 is produced from indium tin oxide and has a thickness of 100 nm to 150 nm. The substrate 116 forms a film of polyethylene naphthalate having a thickness of 125 μm.

FIG. 4A shows a further illustrative working example of a first layer stack 112 and of a second layer stack 114 of a perovskite-based multi-junction solar cell 110.

The first layer stack 112 may comprise the substrate 116, the first electrode 118, two first layers 120 and the perovskite layer 124. The first electrode 118 may have been applied atop the substrate 116. The two first layers 120 may have been applied atop the first electrode 118. The perovskite layer 124 may have been applied atop the two first layers 120. The two first layers 120 may be electron transport layers 136, especially two essentially mutually superposed electron transport layers 136.

The substrate 116 may comprise polyethylene naphthalate (PEN). In particular, the substrate 116 may be or comprise a film of polyethylene naphthalate (PEN). The substrate 116 may have a thickness of 125 μm.

The first electrode 118 may comprise indium tin oxide (ITO). The first electrode 118 may have a thickness of 300 nm.

The two first layers 120 may be two electron transport layers 136, especially a first electron transport layer 154 and a second electron transport layer 156. The first electron transport layer 154 may comprise tin oxide (SnOₓ). The first electron transport layer 154 may have a thickness of 35 nm. The second electron transport layer 156 may comprise fullerene (C60). The second electron transport layer 156 may have a thickness of 20 nm.

The perovskite layer 124 may comprise Cs_{0.1}(MA_{0.17}FA_{0.83})_{0.9}Pb(I_{0.83}Br_{0.17})₃. The perovskite layer 124 may have a thickness of 370 nm.

The second layer stack 114 may comprise the second electrode 128, the absorber layer 130, and three second layers 134. The absorber layer 130 may have been applied atop the second electrode 128. The three second layers 134 may have been applied atop the absorber layer 130. The three second layers 134 may be one recombination layer 132 and two hole transport layers 122, especially three essentially mutually superposed second layers 134.

The second electrode 128 may comprise indium tin oxide (ITO). The second electrode 128 may have a thickness of 70 nm.

The absorber layer 130 may comprise a silicon solar cell 152. The silicon solar cell 152 may have the following architecture: a-Si:H<n>/a-Si:H<i>/c-Si wafer <n>/a-Si:H<i>/a-Si:H<p>. The junction may be a heterojunction. The silicon solar cell 152 may have been polished on both sides. The silicon solar cell 152 may have a thickness of 280 μm.

The recombination layer 132 may lie atop the absorber layer 130. The recombination layer 132 may comprise indium tin oxide (ITO). The recombination layer 132 may have a thickness of 30 nm.

The two hole transport layers 122, especially a first hole transport layer 158 and a second hole transport layer 160, may lie atop the recombination layer 132. The first hole transport layer 158 may lie atop the recombination layer 132 and the second hole transport layer 160 may lie atop the first hole transport layer 158. The first hole transport layer 158 may comprise nickel oxide (NiOₓ). The first hole transport layer 158 may have a thickness of 20 nm. The second hole transport layer 160 may comprise a self-assembly monolayer, especially 2PACz ([2-(9H-carbazol-9-yl)ethyl]phosphonic acid).

The perovskite-based multi-junction solar cell 110 according to FIG. 4A may have been produced with the following lamination parameters: 80 MPa, 90° ° C., 5 min.

The perovskite-based multi-junction solar cell 110 according to FIG. 4A may especially be a laminated monolithic silicon/perovskite multi-junction solar cell. The perovskite-based multi-junction solar cell 110 according to FIG. 4A may have an efficiency of 20.6%, an open-circuit voltage of 1.75 V, a short-circuit current density of 16.0 mA/cm² and a fill factor of 73.7%.

FIG. 4B shows measurement data for the working example according to FIG. 4A. A current density J in mA/cm² is shown as a function of a voltage U in V. The solid line shows a measurement in the reverse direction; the dotted line shows a measurement in the forward direction.

From the J-U curve, it is possible to read the above-described efficiency of 20.6%, the open-circuit voltage of 1.75 V, the short-circuit current density of 16.0 mA/cm² and the fill factor of 73.7% of the one perovskite-based multi-junction solar cell 110. The point of maximum power is at (1.45 V; 14.2 mA/cm²) measured in reverse direction, corresponding to an output power of 20.6 mW/cm².

The open-circuit voltage of the one perovskite-based multi-junction solar cell 110 approaches the added voltage of the two perovskite and silicon solar cells, which shows that both solar cells contribute to the power.

The current density-voltage characteristic including the low hysteresis underlines that the perovskite layer 124 and silicon solar cell 152, in spite of the high temperature and the high pressure that are employed during the lamination process, are of high quality, and no serious deterioration is to be expected.

FIGS. 5A to 5H show further illustrative working examples of a first layer stack 112 and a second layer stack 114 of a perovskite-based multi-junction solar cell 110.

In all working examples according to FIGS. 5A to 5H, the first layer stack 112 may comprise the substrate 116 and the first electrode 118. The first electrode 118 may have been applied atop the substrate 116. The substrate 116 may comprise glass, especially flexible glass. The substrate 116 may have a thickness of 50 μm to 5 mm, especially of 100 μm to 250 μm. The first electrode 118 may comprise indium tin oxide (ITO). The first electrode 118 may have a thickness of 100 nm to 500 nm, especially of 120 nm to 300 nm.

In all working examples according to FIGS. 5A to 5H, the second layer stack 114 may comprise a further substrate 162, the second electrode 128, the absorber layer 130, and a second layer 134 which is a recombination layer 132.

The further substrate 162 may comprise glass. The further substrate 162 may have a thickness of 50 μm to 5 mm, especially of 1 mm.

The second electrode 128 may especially comprise molybdenum (Mo). The second electrode 128 may have a thickness of 0.1 μm to 2 μm, especially of 0.2 μm to 1 μm. The second electrode 128 may be disposed between the further substrate 162 or the absorber layer 130.

The absorber layer 130 may comprise a copper-indium-gallium diselenide (CIGS) solar cell 164. The CIGS solar cell 164 may have a thickness of 1 μm to 5 μm. A surface 168 of the CIGS solar cell 164 may have a root mean square roughness of 1 nm to 2 μm. The surface 168 may be a surface remote from the further substrate 162. The second layer 134, especially the recombination layer 132, may lie atop the surface 168 of the CIGS solar cell 164 with a thickness of 1 μm to 5 μm.

The recombination layer 132 may comprise indium tin oxide (ITO). The recombination layer 132 may have a thickness of 15 nm to 100 nm, especially of 30 nm to 70 nm.

The first layer stacks 122 and the second layer stacks 114 of the working examples according to FIGS. 5A to 5H may additionally each comprise further layers, especially at least one perovskite layer 124 having a thickness of 100 nm to 2 μm, especially of 300 nm to 800 nm, a hole transport layer 122 and an electron transport layer 136.

The hole transport layer 122 may comprise nickel oxide (NiOₓ). The hole transport layer 122 composed of nickel oxide (NiOₓ) may have a thickness of 10 nm to 50 nm, especially of 20 nm to 30 nm. In addition, the hole transport layer 122 may comprise a self-assembly monolayer, especially 2PACz ([2-(9H-carbazol-9-yl)ethyl]phosphonic acid).

The electron transport layer 136 may comprise tin oxide (SnOₓ) and have a thickness of 10 nm to 50 nm, especially of 30 nm to 40 nm. In addition, the electron transport layer 136 may comprise fullerene (C60) and have a thickness of 10 nm to 30 nm, especially of 20 nm to 25 nm.

In the working example according to FIG. 5A, the first layer stack 112 may comprise the hole transport layer 122 and the perovskite layer 124. The hole transport layer 122 may lie atop the first electrode 118. The perovskite layer 124 may lie atop the hole transport layer 122.

In addition, in the working example according to FIG. 5A, the second layer stack 114 may comprise the electron transport layer 136. The electron transport layer 136 may lie atop the recombination layer 132.

In the working example according to FIG. 5B, the first layer stack 112 may comprise the electron transport layer 136 and the perovskite layer 124. The electron transport layer 136 may lie atop the first electrode 118. The perovskite layer 124 may lie atop the electron transport layer 136.

In addition, in the working example according to FIG. 5B, the second layer stack 114 may comprise the hole transport layer 122. The hole transport layer 122 may lie atop the recombination layer 132.

In the working example according to FIG. 5C, the first layer stack 112 may comprise the hole transport layer 122. The hole transport layer 122 may lie atop the first electrode 118.

In addition, in the working example according to FIG. 5C, the second layer stack 114 may comprise the electron transport layer 136 and the perovskite layer 124. The electron transport layer 136 may lie atop the recombination layer 132. The perovskite layer 124 may lie atop the electron transport layer 136.

In the working example according to FIG. 5D, the first layer stack 112 may comprise the electron transport layer 136. The electron transport layer 136 may lie atop the first electrode 118.

In addition, in the working example according to FIG. 5D, the second layer stack 114 may comprise the hole transport layer 122 and the perovskite layer 124. The hole transport layer 122 may lie atop the recombination layer 132. The perovskite layer 124 may lie atop the hole transport layer 122.

In the working example according to FIG. 5E, the first layer stack 112 may comprise the hole transport layer 122 and the perovskite layer 124. The hole transport layer 122 may lie atop the first electrode 118. The perovskite layer 124 may lie atop the hole transport layer 122.

In addition, in the working example according to FIG. 5E, the second layer stack 114 may comprise the electron transport layer 136 and a further perovskite layer 166. The electron transport layer 136 may lie atop the recombination layer 132. The further perovskite layer 166 may lie atop the electron transport layer 136.

In the working example according to FIG. 5F, the first layer stack 112 may comprise the electron transport layer 136 and the perovskite layer 124. The electron transport layer 136 may lie atop the first electrode 118. The perovskite layer 124 may lie atop the electron transport layer 136.

In addition, in the working example according to FIG. 5F, the second layer stack 114 may comprise the hole transport layer 122 and the further perovskite layer 166. The hole transport layer 122 may lie atop the recombination layer 132. The further perovskite layer 166 may lie atop the hole transport layer 122.

In the working example according to FIG. 5G, the first layer stack 112 may comprise the hole transport layer 122. The hole transport layer 122 may lie atop the first electrode 118.

In addition, in the working example according to FIG. 5G, the second layer stack 114 may comprise the electron transport layer 136, the perovskite layer 124 and the further perovskite layer 166. The electron transport layer 136 may lie atop the recombination layer 132. The perovskite layer 124 may lie atop the electron transport layer 136. The further perovskite layer 166 may lie atop the perovskite layer 124. The perovskite layer 124 and the further perovskite layer 166 may have been applied successively by sequential lamination.

In the working example according to FIG. 5H, the first layer stack 112 may comprise the electron transport layer 136. The electron transport layer 136 may lie atop the first electrode 118.

In addition, in the working example according to FIG. 5H, the second layer stack 114 may comprise the hole transport layer 122, the perovskite layer 124 and the further perovskite layer 166. The hole transport layer 122 may lie atop the recombination layer 132. The perovskite layer 124 may lie atop the hole transport layer 122. The further perovskite layer 166 may lie atop the perovskite layer 124.

### LIST OF REFERENCE NUMERALS

110 perovskite-based multi-junction solar cell
112 first layer stack
114 second layer stack
116 substrate
118 first electrode
120 first layer
122 hole transport layer
124 perovskite layer
126 first concluding layer
128 second electrode
130 absorber layer
132 recombination layer
134 second layer
136 electron transport layer
137 buffer layer
138 second concluding layer
140 lower plate
142 upper plate
144 arrow
146 heating phase
148 lamination phase
150 cooling phase
152 silicon solar cell
154 first electron transport layer
156 second electron transport layer
158 first hole transport layer
160 second hole transport layer
162 further substrate
164 CIGS solar cell
166 further perovskite layer
168 surface

1. A method of producing a perovskite-based multi-junction solar cell, wherein the method comprises the following steps:
a) producing a first layer stack, where the first layer stack comprises at least one substrate, at least one first electrode and at least one first layer;
b) producing a second layer stack, where the second layer stack comprises at least one absorber layer and at least one second layer;
wherein, in step a), a perovskite layer is introduced into the first layer stack or, in step b), the perovskite layer is introduced into the second layer stack, wherein the method further comprises the following steps:
c) applying the first layer stack to the second layer stack;
d) laminating the first layer stack to the second layer stack, in such a way that at least one connection selected from the group consisting of: a mechanical connection, an electrical connection, is formed between the first layer stack and the second layer stack, forming the perovskite-silicon multi-junction solar cell;
wherein the first layer and the second layer are each selected from the group consisting of: a hole transport layer, an electron transport layer, a buffer layer, a recombination layer, an electrode layer, where the perovskite layer forms a laminate-forming layer either of the first layer stack or of the second layer stack.

2. The method as claimed in claim 1, wherein the second layer stack comprises at least one second electrode.

3. The method as claimed in claim 1, wherein the first layer stack has a first concluding layer, wherein the second layer stack has a second concluding layer, wherein, in step c), the first layer stack is applied to the second layer stack in such a way that the first concluding layer of the first layer stack and the second concluding layer of the second layer stack lie atop one another.

4. The method as claimed in claim 3, wherein the perovskite layer forms the first concluding layer, wherein the electron transport layer or the hole transport layer forms the second concluding layer, or vice versa.

5. The method as claimed in claim 1, wherein the substrate and/or at least one layer of the first layer stack and/or of the second layer stack have a textured surface having at least one texture.

6. The method as claimed in claim 5, wherein the textured surface has a root mean square roughness of greater than 2 nm, especially of greater than 250 nm.

7. The method as claimed in claim 5, wherein the textured surface has a distance between a highest point and a lowest point of 20 nm to 100 μm, especially of 500 nm to 10 μm.

8. The method as claimed in claim 5, wherein at least one side of the perovskite-based multi-junction solar cell selected from the group consisting of: a sunlight-facing outer face of the perovskite-based multi-junction solar cell, a reverse side of the perovskite-based multi-junction solar cell; has the textured surface.

9. The method as claimed in claim 5, wherein the texture is a nanotexturing or a microtexturing.

10. The method as claimed in claim 1, wherein the substrate and/or at least one layer of the first layer stack and/or of the second layer stack has at least one rough surface.

11. The method as claimed in claim 10, wherein the rough surface has a root mean square roughness of 1 nm to 2 μm, especially of 50 nm to 300 nm.

12. The method as claimed in claim 10, wherein the rough surface has a distance between a highest point and a lowest point of 1 nm to 10 μm, especially of 10 nm to 1 μm.

13. The method as claimed in claim 1, wherein the perovskite layer is applied to the first layer stack or to the second layer stack by at least one method selected from the group consisting of: thermal evaporation, rotary coating, blade coating, inkjet printing, spray coating, slot die coating, roll coating, gravure printing methods.

14. The method as claimed in claim 1, wherein, prior to performance of step d) the perovskite in the perovskite layer is in the solid phase.

15. The method as claimed in claim 1, wherein steps a)-d) are adhesive-free method steps.

16. The method as claimed in claim 1, wherein the perovskite layer has a layer thickness of 800 nm to 10 μm.

17. The method as claimed in claim 1, wherein the perovskite layer takes the form of a planar layer.

18. A perovskite-based multi-junction solar cell, wherein the perovskite-based multi-junction solar cell comprises:
at least one first layer stack, where the first layer stack comprises at least one first electrode and at least one first layer;
at least one second layer stack, where the second layer stack HA comprises at least one absorber layer and at least one second layer;
where the first layer stack has been applied to the second layer stack, where the first layer stack has been laminated onto the second layer stack such that at least one connection selected from the group consisting of: a mechanical connection, an electrical connection, has been formed between the first layer stack and the second layer stack, wherein the first layer and the second layer are each selected from the group consisting of: a hole transport layer, an electron transport layer, a buffer layer, a recombination layer, an electrode layer, where the first layer stack or the second layer stack comprises a perovskite layer, where the perovskite layer forms a laminate-forming layer either of the first layer stack or of the second layer stack.

19. The perovskite-based multi-junction solar cell as claimed in claim 18, wherein the first layer stack also comprises at least one substrate.

20. The perovskite-based multi-junction solar cell as claimed in claim 19, wherein the substrate comprises glass, wherein the first electrode comprises indium tin oxide (ITO), wherein the second layer stack comprises a further substrate, wherein the further substrate comprises glass, wherein the second layer is a recombination layer, wherein the recombination layer comprises indium tin oxide (ITO), wherein the absorber layer comprises a copper-indium-gallium diselenide (CIGS) solar cell, wherein the second layer stack further comprises a second electrode, wherein the second electrode comprises molybdenum (Mo).

21. The perovskite-based multi-junction solar cell as claimed in claim 20, wherein a surface of the CIGS solar cell has a root mean square roughness of 1 nm to 2 μm.

22. The perovskite-based multi-junction solar cell as claimed in claim 20, wherein the perovskite-based multi-junction solar cell further comprises at least one hole transport layer, wherein the hole transport layer comprises nickel oxide or a self-assembly monolayer, wherein the perovskite-based multi-junction solar cell further comprises at least one electron transport layer, wherein the electron transport layer comprises tin oxide or fullerene.

23. The perovskite-based multi-junction solar cell as claimed in claim 19, where the first layer stack comprises two of the first layers and the perovskite layer, wherein the two first layers comprise a first electron transport layer and a second electron transport layer, wherein the first electron transport layer comprises tin oxide, wherein the second electron transport layer comprises fullerene, wherein the substrate comprises polyethylene naphthalate (PEN), wherein the first electrode comprises indium tin oxide (ITO), wherein the second layer stack further comprises a second electrode, wherein the second electrode comprises indium tin oxide (ITO), wherein the second layer stack also comprises three second layers, wherein the three second layers comprise a first hole transport layer, a second hole transport layer and a recombination layer, wherein the first hole transport layer comprises nickel oxide, wherein the second hole transport layers comprises a self-assembly monolayer, wherein the recombination layer comprises indium tin oxide (ITO), wherein the absorber layer comprises a silicon solar cell.

24. The perovskite-based multi-junction solar cell as claimed in claim 23, wherein the silicon solar cell is polished on both sides.
